(19) United States
(12) Patent Application Publication
(10) Pub. No.: US 2023/0116427 A1
(43) Pub. Date: Apr. 13, 2023

(54) SYSTEMS AND METHODS FOR PURGING REACTOR LOWER CHAMBERS WITH ETCHANTS DURING FILM DEPOSITION

(71) Applicant: ASM IP Holding B.V., Almere (NL)

(72) Inventors: Junwei Su, Tempe, AZ (US); Jiwen Xiang, Gilbert, AZ (US); Shujin Huang, Tempe, AZ (US); Loc Vinh Tran, Gilbert, AZ (US); Wentao Wang, Chandler, AZ (US); Xing Lin, Chandler, AZ (US)

(21) Appl. No.: 17/962,009

(22) Filed: Oct. 7, 2022

Related U.S. Application Data
(60) Provisional application No. 63/254,691, filed on Oct. 12, 2021.
(60) Provisional application No. 63/282,506, filed on Nov. 23, 2021.

(51) Int. Cl. C23C 16/44; H01L 21/687; H01L 21/02; C23C 16/52; C23C 16/02; C23C 16/24

(52) U.S. Cl. CPC C23C 16/4408; H01L 21/68742; H01L 21/68764; H01L 21/02532; H01L 21/0262; C23C 16/4405; C23C 16/52; C23C 16/0272; C23C 16/24

(57) ABSTRACT

A semiconductor processing system includes a gas delivery module, and a chamber body connected to the gas delivery module. The divider has an aperture, is fixed within an interior of the chamber body, and separates an interior of the chamber body into upper and lower chambers, the aperture fluidly coupling the lower chamber to the upper chamber. A susceptor is arranged within the aperture. A controller is operably connected to the gas delivery module to purge the lower chamber with a first purge flow including an etchant while etching the upper chamber, purge the lower chamber with a second purge flow including the etchant while depositing a precoat in the upper chamber, and purge the lower chamber with a third purge flow including the etchant while depositing a film onto a substrate in the upper chamber. Film deposition methods and lower chamber etchant purge kits are also described.

### CROSS-REFERENCE TO RELATED APPLICATIONS

This application is a nonprovisional of, and claims priority to and the benefit of, U.S. Provisional Patent Application No. 63/254,691, filed on Oct. 12, 2021 and entitled “Method and Apparatus to Prevent Lower Chamber Coating Issue in EPI Reactor,” and U.S. Provisional Patent Application No. 63/282,506, filed on Nov. 23, 2021 and entitled “SYSTEMS AND METHODS FOR PURGING REACTOR LOWER CHAMBERS WITH ETCHANTS DURING FILM DEPOSITION,” the contents of which are hereby incorporated by reference herein.

### FIELD OF INVENTION

The present disclosure generally relates to fabricating semiconductor devices. More particularly, the present disclosure relates to depositing films onto substrates during the fabrication of semiconductor devices using semiconductor processing systems.

### BACKGROUND OF THE DISCLOSURE

Semiconductor devices, such as integrated circuits and power electronics, are commonly fabricated by depositing films onto substrates. Film deposition is generally accomplished by positioning a substrate (e.g., a silicon wafer) into a reactor, heating the substrate of a desired deposition temperature, and flowing a film precursor through the reactor. As the film precursor flows through the reactor a chemical reaction occurs, which causes a film to be deposited onto the substrate. Once the film reaches a desired thickness the flow of film precursor ceases, and the substrate unloaded from the reactor. Unloading may be accomplished by driving lift pins upwards through the substrate support from a retracted position to an extended position, and thereafter allowing the lift pins to return the retracted position using gravity. Use of gravity to return the lift pins to the retracted position allows the substrate support to rotate relative a lift pin actuator, simplifying the arrangement of the reactor.

During some deposition operations material may accumulate on the lift pins while in the retracted position. Without being bound by a particular theory or mode of operation, it is believed film precursor and/or reaction products may cause material to accumulate on exposed structures and surfaces below the substrate support. Once present, the material is conveyed into the through-holes by the lift pin during substrate unseating from the substrate support, reducing clearance between the lift pins and the substrate support within the substrate support, potentially causing the lift pins to bind within the through-holes during seating of a subsequent substrate on the substrate support. Once bound, intervention may be required to free the lift pins in order to avoid damage to the substrate and/or components of the reactor.

Various countermeasures exist for lift pin binding. For example, springs arranged between the substrate support and lugs on the lift pins may compress during movement of the lift pins from the retracted position to the extended position, the springs urging the lift pins downward to return the lift pins to the retracted position. Lift pin weights may also be employed to urge the lift pins downward during return to the retracted position. And through-holes defined in the substrate support slidably receiving the lift pins may be oversized with respect to the width of the lift pins to provide additional clearance within the through-holes between the lift pins and the substrate support to reduce the tendency that accumulated material carried by the lift pins causes binding within the through-holes extending through the substrate support structure.

Such methods and systems have generally been considered suitable for their intended purpose. However, there remains a need in the art for improved semiconductor processing systems, film deposition methods, and lower chamber etchant purge kits for semiconductor processing systems employed for film deposition. The present disclosure provides a solution to this need.

### SUMMARY OF THE DISCLOSURE

A semiconductor processing system is provided. The semiconductor processing system includes a gas delivery module, a divider, a chamber body, a susceptor, and a controller. The chamber body is connected to the gas delivery module. The divider has an aperture, is fixed in an interior of the chamber body, and separates an interior of the chamber body into upper and lower chambers such that the aperture fluidly coupling the lower chamber to the upper chamber. The susceptor is arranged within the aperture and is supported for within the chamber body for rotation about a rotation axis. The controller is operably connected to the gas delivery module to purge the lower chamber with a first purge flow including an etchant while etching the upper chamber, purge the lower chamber with a second purge flow including the etchant while depositing a precoat in the upper chamber, and purge the lower chamber with a third purge flow including the etchant while depositing a film onto a substrate seated on the susceptor in the upper chamber.

In addition to one or more of the features described above, or as an alternative, further examples of the system may include that the first purge flow includes a first etchant mass fraction, that the second purge flow includes a second etchant mass fraction, and that the third purge flow includes a third etchant mass fraction. The third etchant mass fraction may be smaller than the second etchant mass fraction. The second etchant mass fraction may be smaller than the first etchant mass fraction.

In addition to one or more of the features described above, or as an alternative, further examples of the system may include that the gas delivery module includes an etchant source and that the system further includes an injection flange. The injection flange may be connected to the chamber body. The injection flange may fluidly couple the etchant source to the lower chamber and therethrough to the upper chamber of the chamber body.

In addition to one or more of the features described above, or as an alternative, further examples of the system may include that the gas delivery module includes an etchant source and that the system include an exhaust flange. The exhaust flange may be connected to the chamber body. The exhaust flange may fluidly couple the etchant source to the lower chamber and therethrough to the upper chamber.

In addition to one or more of the features described above, or as an alternative, further examples of the system may include that the gas delivery module includes an etchant source and that the system further includes a tube member. The tube member may be connected to a lower wall of the chamber body. The tube member may fluidly couple the etchant source to the lower chamber and therethrough to the upper chamber of the chamber body.

In addition to one or more of the features described above, or as an alternative, further examples of the system may include an injection flange connected to the chamber body; a purge conduit connected to the injection flange, the purge conduit fluidly coupled to the lower chamber and therethrough to the upper chamber by the injection flange; an etchant mass flow controller connected to the purge conduit; and a carrier/purge gas mass flow controller connected to the purge conduit. The controller may be operably connected to the etchant mass flow controller and the carrier/purge gas mass flow controller to provide a co-flow of the etchant and a carrier/purge gas to the lower chamber.

In addition to one or more of the features described above, or as an alternative, further examples of the system may include that the injection flange includes a deposition header.

The deposition header may fluidly couple the gas delivery module to the upper chamber and therethrough to the lower chamber.

In addition to one or more of the features described above, or as an alternative, further examples of the system may include that the injection flange includes an etch header. The etch header may fluidly couple the gas delivery module to the upper chamber of the chamber body and therethrough to the lower chamber.

In addition to one or more of the features described above, or as an alternative, further examples of the system may include that the gas delivery module includes an etchant source. The etchant source may be connected to the lower chamber such that the etchant provided to the lower chamber in at least one of the first purge flow, the second purge flow, and the third purge flow etches a shank portion of a lift pin disposed in the lower chamber.

A film deposition method is provided. The film deposition method includes, at a semiconductor processing system as described above, purging the lower chamber with a first purge flow including an etchant while etching the upper chamber of the chamber body, purging the lower chamber with a second purge flow including the etchant while depositing a precoat in the upper chamber of the chamber body, and purging the lower chamber with a third purge flow including the etchant while depositing a film onto a substrate seated on the susceptor in the upper chamber.

In addition to one or more of the features described above, or as an alternative, further examples of the method may include that the first purge flow includes a first etchant mass fraction, that the second purge flow includes a second etchant mass fraction, and that the second etchant mass fraction is smaller than the first etchant mass fraction.

In addition to one or more of the features described above, or as an alternative, further examples of the method may include that the second purge flow includes a second etchant mass fraction, that the third purge flow includes a third etchant mass fraction, and that the third etchant mass fraction is smaller than the second etchant mass fraction.

In addition to one or more of the features described above, or as an alternative, further examples of the method may include that the first purge flow includes a first etchant mass fraction, that the third purge flow includes a third etchant mass fraction, and that the third etchant mass fraction is smaller than the first etchant mass fraction.

In addition to one or more of the features described above, or as an alternative, further examples of the method may include ceasing flow of the etchant into the lower chamber between the first purge flow and the second purge flow and ceasing flow of the etchant into the lower chamber between the second purge flow and the third purge flow. The third purge flow may include the etchant during only a terminal portion of the interval during which the film is deposited onto the substrate in the upper chamber.

In addition to one or more of the features described above, or as an alternative, further examples of the method may include that the terminal portion is less than 50%, or less than 40%, or less than 30% of the interval during which the film is deposited onto the substrate.

In addition to one or more of the features described above, or as an alternative, further examples of the method may include heating the susceptor to a first temperature prior to purging the lower chamber with a first purge flow, heating the susceptor to a second temperature prior to purging the lower chamber with a second purge flow, and heating the susceptor to a third temperature prior to purging the lower chamber with a third purge flow. The second temperature may be less than the first temperature. The third temperature may be greater than the second temperature.

In addition to one or more of the features described above, or as an alternative, further examples of the method may include that the purging the lower chamber with a first purge flow includes flowing hydrochloric acid (HCl) into the lower chamber while HCl is flowed through the upper chamber. The HCl flowed into the lower chamber may etch a material accumulation on a shank portion of lift pin disposed in the lower chamber.

In addition to one or more of the features described above, or as an alternative, further examples of the method may include that the purging the lower chamber with a second purge flow includes flowing HCl into the lower chamber while a silicon-containing precoat precursor is flowed through the upper chamber. The HCl flowed into the lower chamber may etch material accumulation on a shank portion of lift pin disposed in the lower chamber.

In addition to one or more of the features described above, or as an alternative, further examples of the method may include that the purging the lower chamber with a third purge flow comprises flowing HCl into the lower chamber while a silicon-containing film precursor is flowed through the upper chamber, wherein the HCl flowed into the lower chamber etches a material accumulation on a shank portion of lift pin disposed in the lower chamber.

A lower chamber etchant purge kit is provided. The kit includes an etchant conduit, a tee fitting, an etchant mass flow controller (MFC), and a computer program product. The etchant conduit id configured to fluidly couple an etchant source to a lower chamber of a chamber body. The tee fitting is configured to fluidly couple a carrier/purge source to the etchant conduit for intermixing a carrier/purge gas with an etchant flowing through the etchant conduit. The etchant MFC is configured to control mass fraction of the etchant intermixed with the carrier/purge gas provided to the lower chamber of the chamber body. The computer program product includes instructions that, when read by a controller, cause the controller to (a) purge a lower chamber of a chamber body with a first purge flow including the etchant using the etchant MFC while etching an upper chamber of the chamber body, (b) purge the lower chamber with a second purge flow including the etchant using the etchant MFC while depositing a precoat in the upper chamber of the chamber body, and (c) purge the lower chamber with a third purge flow including the etchant using the etchant MFC while depositing a film onto a substrate seated in the upper chamber of the chamber body.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing a gas delivery module connected to a reactor and providing purge flows to a lower chamber of the reactor;

FIG. 2 is a schematic view of the semiconductor processing system of FIG. 1 including the gas delivery module and a controller, showing the gas delivery module operably associated with the controller to provide the purge flows to the reactor;

FIGS. 3 and 4 are schematic views of the semiconductor processing system of FIG. 1, showing lift pins slidably received in a substrate support and disposed at a retracted position and an extended position, respectively;

FIG. 5 is a schematic view of the semiconductor processing system of FIG. 1 including the reactor, showing the gas delivery module providing a first purge flow including etchant to the lower chamber of the reactor to limit material on surfaces and structures in the lower chamber while an upper chamber of the reactor is etched;

FIG. 6 is a schematic view the semiconductor processing system of FIG. 1 including the reactor, showing the gas delivery module providing a second purge flow to the lower chamber of the reactor including etchant to limit material on surfaces and structures in the lower chamber while a precoat is deposited in the upper chamber of the reactor;

FIG. 7 is a schematic view of the semiconductor processing system of FIG. 1 including the reactor, showing the gas delivery module providing a third purge flow including etchant to the lower chamber of the reactor to limit material on surfaces and structures in the lower chamber while a film is deposited onto a substrate in the upper chamber of the reactor;

FIG. 8 is a schematic view of the semiconductor processing system of FIG. 1 according to an example, showing a lower chamber etchant purge kit connecting the gas delivery module to the reactor through an injection flange of the reactor;

FIG. 9 is a schematic view of the semiconductor processing system of FIG. 1 according to another example, showing a lower chamber etchant purge kit connecting the gas delivery module to the reactor through a tube member of the reactor;

FIG. 10 is a schematic view of the semiconductor processing system of FIG. 1 according to a further example, showing a lower chamber etchant purge kit connecting the gas delivery module to the reactor through an exhaust flange and divider of the reactor;

FIG. 11 is a chart set of temperature and etchant mass fraction in the lower chamber of reactor versus time in the reactor of FIG. 1 according to an example, showing etchant mass fraction changing over time in purge flows provided to the lower chamber of the reactor to limit both material accumulation on surfaces and structures in the lower chamber and etching of the film deposited onto a substrate in the upper chamber of the reactor; and

FIGS. 12-17 are block diagrams of a film deposition method, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

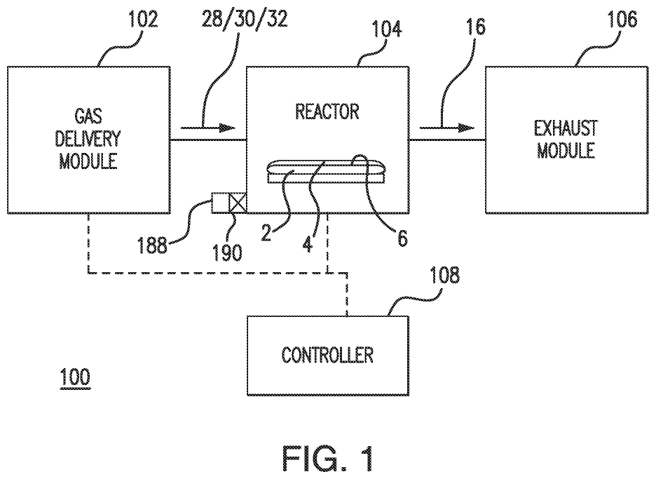

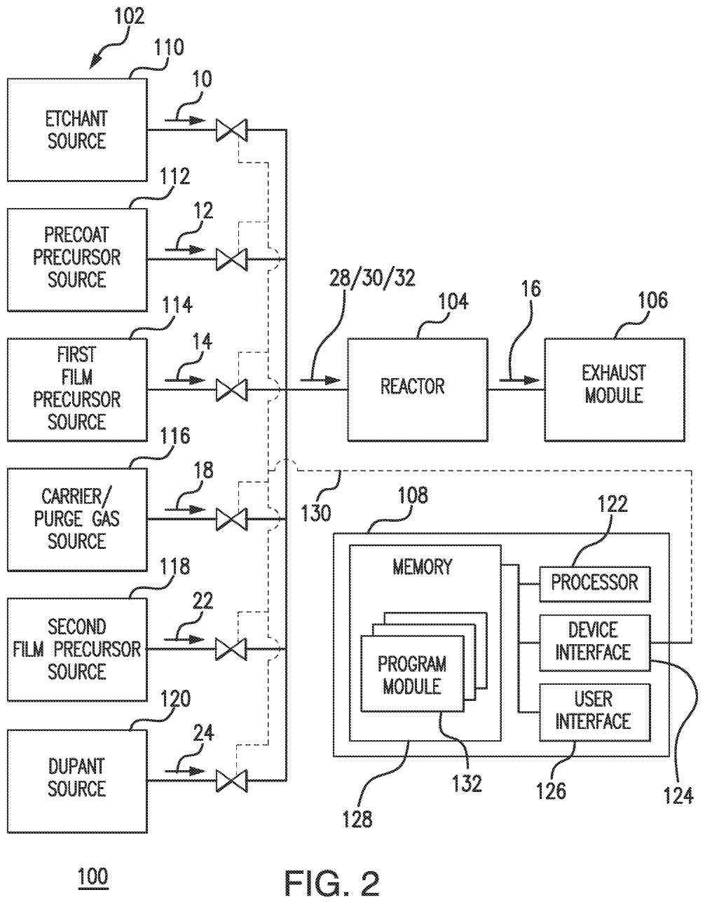

Reference will now be made to the drawings wherein like reference numerals identify similar structural features or aspects of the subject disclosure. For purposes of explanation and illustration, and not limitation, a partial view of an example of a semiconductor processing system in accordance with the present disclosure is shown in FIG. 1 and is designated generally by reference character 100. Other examples of semiconductor processing systems, film deposition methods, and lower chamber etchant purge kits in accordance with the present disclosure, or aspects thereof, are provided in FIGS. 2-17, as will be described. The systems and methods of the present disclosure may be used to limit accumulation of material (or remove accumulated material) on surfaces and structures in lower chambers of reactors employed to deposits films onto substrates, such as onto lift pins in reactors employed to deposit thick epitaxial films onto substrates during the fabrication of power electronics semiconductor for epitaxy, through the present disclosure is not limited any particular structure or to film deposition process in general.

Referring to FIG. 1, the semiconductor processing system 100 is shown. The semiconductor processing system 100 includes a gas delivery module 102, a reactor 104, an exhaust module 106, and a controller 108. The gas delivery module 102 is connected to the reactor 104 and is configured to provide flows of one or more of an etchant 10, a precoat precursor 12, and a film precursor 14 to the reactor 104. The exhaust module 106 is connected to the reactor 104, is fluidly coupled to the gas delivery module 102 by the reactor 104, and is configured to receive a flow of decomposition products, residual precursor, and/or reaction products 16 issued by the reactor 104. The reactor 104 is connected to the gas delivery module 102 and the exhaust module 106, fluidly couples the gas delivery module 102 to the exhaust module 106, and is configured to support a substrate 2 during deposition of a film 4 onto an upper surface 6 of the substrate 2. It is contemplated that the controller 108 be operably connected to one or more of the gas delivery module 102, the reactor 104, and the exhaust module 106 to control operation of the semiconductor processing system 100. In certain examples the exhaust module 106 may include a vacuum pump and/or an abatement device, such as a scrubber apparatus.

With reference to FIG. 2, the gas delivery module 102 and the controller 108 are shown according to an example. In the illustrated example the gas delivery module 102 includes an etchant source 110, a precoat precursor source 112, and a film precursor source 114. In the illustrated example the film precursor source 114 is a first film precursor source 114 and the gas delivery module 102 further includes a carrier/purge gas source 116, a second film precursor source 118, and a dopant source 120. Operable association with the gas delivery module 102 and the controller 108 may be accomplished with a valve arrangement, such as a mass flow controller (MFC) arrangement fluidly coupling one or more of the sources to the reactor 104.

The etchant source 110 is connected to the reactor 104 and is configured to provide a flow of an etchant to the reactor 104. In this respect the etchant source 110 includes an etchant 10, is connected to the reactor by etchant valve or MFC, and is in selective fluid communication with the reactor 104 through the etchant valve or MFC. In certain examples the etchant 10 may include a halide-containing material, such as fluorine or chlorine. Examples of suitable halide-containing materials include hydrochloric acid (HCl) and/or precursors employed to generate HCl.

The precoat precursor source 112 is connected to the reactor 104 and is configured to provide a flow of a precoat precursor to the reactor 104. In this respect the precoat precursor source 112 includes a precoat precursor 12, is connected to the reactor 104 by a precoat precursor valve, and is in selective fluid communication with the reactor 104 through the precoat precursor valve. In certain examples the precoat precursor 12 may include a silicon-containing precoat precursor. Examples of suitable silicon-containing precoat precursors include silane (SiH₄), dichlorosilane (DCS), and/or trichlorosilane (TCS).

The first film precursor source 114 is connected to the reactor 104 and is configured to provide a flow of a first film precursor 14 to the reactor 104. In this respect the first film precursor source 114 includes the first film precursor 14, is connected to the reactor 104 by a first film precursor valve, and is in selective fluid communication with the reactor 104 through the first film precursor valve. In certain examples the first film precursor 14 may include a silicon-containing film precursor. Examples of suitable silicon-containing film precursors include silane (SiH₄), dichlorosilane (DCS), and trichlorosilane (TCS).

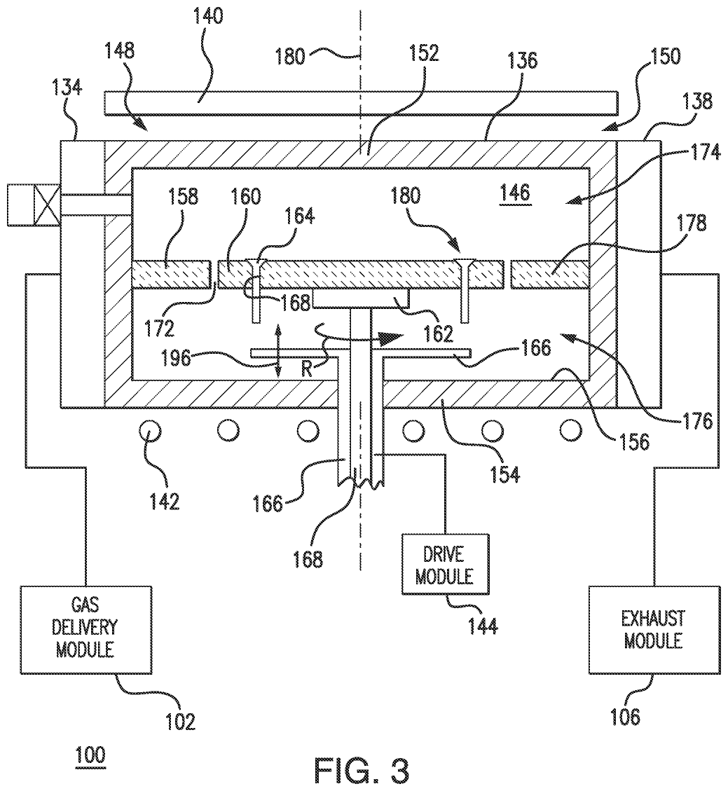

The carrier/purge gas source 116 is connected to the reactor 104 and is configured to provide a flow of a carrier/purge gas 18 to the reactor 104. In this respect the carrier/purge gas source 116 includes a carrier/purge gas 18, is connected to the reactor 104 by a carrier/purge gas valve and a purge conduit to a lower chamber 176 (shown in FIG. 3) of the reactor 104, and is in selective fluid communication with the reactor 104 through the carrier/purge gas valve. In certain examples, the carrier/purge gas valve may be incorporated in a flow control device, such a mass flow controller assembly, and may be operably associated with the controller 108 through the flow control device. In accordance with certain examples, the carrier/purge gas 18 may include hydrogen gas (H₂). It is also contemplated that the carrier/purge gas 18 may include an inert gas such nitrogen (N₂) gas, argon (Ar) gas, and/or helium (He) gas.

The second film precursor source 118 is connected to the reactor 104 and is configured to provide a flow of a second film precursor to the reactor 104. In this respect the second film precursor source 118 includes a second film precursor 20, is connected to the reactor 104 by a second film precursor valve, and is in selective fluid communication with the reactor 104 through the second film precursor valve. In certain examples, the first second film precursor valve may be incorporated in a flow control device, such a mass flow controller assembly, and may be operably associated with the controller 108 through the flow control device. In accordance with certain examples, the second film precursor 20 may include a germanium-containing film precursor. Non-limiting examples of suitable germanium-containing film precursors include germane (GeH₄).

The dopant source 120 is connected to the reactor 104 and is configured to provide a flow of a dopant-containing precursor to the reactor 104. In this respect the dopant source 120 includes a dopant-containing precursor 20, is connected to the reactor 104 by a dopant-containing precursor valve, and is in selective fluid communication with the reactor 104 through the dopant-containing precursor valve. In certain examples, the dopant-containing precursor valve may be incorporated in a flow control device, such a mass flow controller assembly, and may be operably associated with the controller 108 through the flow control device. In accordance with certain examples, the dopant-containing precursor may include an n-type or a p-type dopant such as arsenic (Ar) or phosphorous (P). The gas delivery module 102 may be as shown and described in U.S. Patent Application Publication No. 2020/0040458 A1 to Ma et al., filed on Aug. 6, 2018, the contents of which are incorporated herein by reference in its entirety. However, as will be appreciated by those of skill in the art in view of the present disclosure, other gas delivery modules are possible and remain within the scope of the present disclosure.

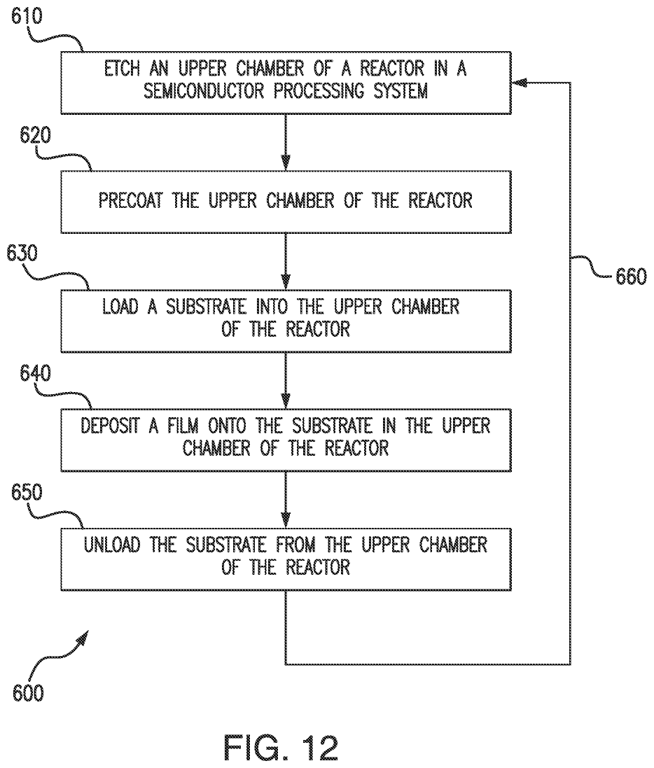

The controller 108 includes a processor 122, a device interface 124, a user interface 126, and a memory 128. The device interface 124 operably connects the controller 108 to the gas delivery module 102, for example, through a wired or wireless link 130. The processor 122 is disposed in communication one or more of the gas delivery module 102 and the reactor 104 through the device interface 124, is operably connected to the user interface 126 to receive and/or provide user input/user output therethrough, and is disposed in communication with the memory 128. The memory 128 includes a non-transitory machine-readable medium having a plurality of program modules 132 recorded on the medium that, when read by the processor 122, cause the processor 122 to undertake certain actions. Among those actions are operations of a film deposition method 600 (shown in FIG. 12), as will be described. Although a specific arrangement of the controller 108 is shown in FIG. 2, it is to be understood and appreciated that other controller arrangements are possible, e.g., controllers having distributed control architectures, and remain within the scope of the present disclosure.

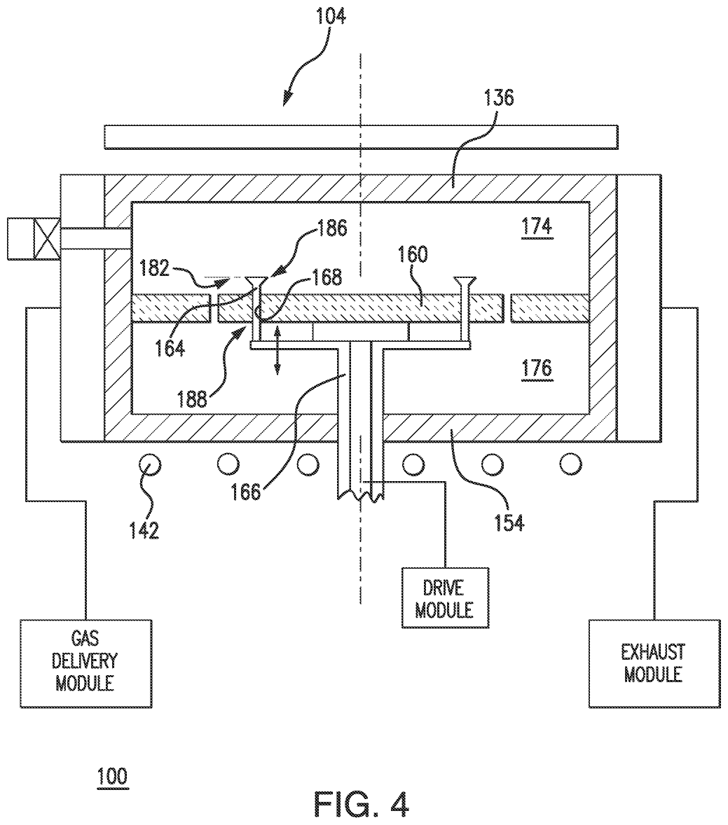

With reference to FIGS. 3 and 4, the reactor 104 is shown according to an example. Referring to FIG. 3, the reactor 104 includes an injection flange 134, a chamber body 136, and an exhaust flange 138. The reactor 104 also includes an upper lamp bank 140, a lower lamp bank 142, and a drive module 144. The injection flange 134 is connected to the chamber body 136 and couples the gas delivery module 102 to an interior 146 of the chamber body 136. The exhaust flange 138 is connected to the chamber body 136 and fluidly couples the interior 146 of the chamber body 136 to the exhaust module 106. The upper lamp bank 140 and the lower lamp bank 142 are supported above and below the chamber body 136, respectively, are operably associated with the controller 108 (shown in FIG. 2), and are configured to radiantly communicate heat into the interior 146 of the chamber body 136.

The chamber body 136 has in injection end 148 and an opposite (relative to the general direction of fluid flow through the interior 146 of the chamber body 136) exhaust end 150, has an upper wall 152 and a lower wall 154, and is formed from a transparent material 156 (e.g., a material transmissive to radiant energy communicated by the upper lamp bank 140 and the lower lamp bank 142), and may be a ceramic material such as quartz. The injection flange 134 is connected to the injection end 148 of the chamber body 136 and fluidly couples the gas delivery module 102 to the interior 146 of the chamber body 136. The exhaust flange 138 is connected to the exhaust end 150 of the chamber body 136 and fluidly couples the interior 146 of the chamber body 136 to the exhaust module 106. The upper wall 152 of the chamber body 136 extends between the injection end 148 and the exhaust end 150 of the chamber body 136, and radiantly couples the upper lamp bank 140 to the interior 146 of the chamber body 136. The lower wall 154 of the chamber body 136 is spaced apart from the upper wall 152 of the chamber body 136 by the interior 146 of the chamber body 136, extends between the injection end 148 and the exhaust end 150 of the chamber body 136, and radiantly couples the lower lamp bank 142 to the interior 146 of the chamber body 136. In certain examples the chamber body 136 may include one or more external ribs extending along exterior surfaces of the chamber body 136. In accordance with certain examples, the chamber may have no external ribs.

The reactor 104 also includes a divider 158, a susceptor 160, and susceptor support 162. The reactor 104 further a plurality of the lift pins 164, a lift pin actuator 166, and a shaft member 170. The divider 158 is fixed within the interior 146 of the chamber body 136, has an aperture 172 extending therethrough, divides the interior 146 of the chamber body 136 into an upper chamber 174 and the lower chamber 176, and is formed from an opaque material 178 (e.g., suitable to absorb radiant energy transmitted by the transparent material 156). The aperture 172 extending through the divider 158 fluidly couples the upper chamber 174 of the chamber body 136 to the lower chamber 176 of the chamber body 136. In certain examples, the opaque material 178 may include a bulk graphite material, which may have a silicon carbide coating overlaying the bulk graphite material.

The susceptor 160 is arranged within the interior 146 of the chamber body 136 and in the aperture 172, is supported for rotation R about a rotation axis 180, and is configured to seat thereon the substrate 2 (shown in FIG. 1) during the deposition of the film 4 (shown in FIG. 1) onto the upper surface 6 (shown in FIG. 1) of the substrate 2. The susceptor 160 may also be formed from an opaque material, e.g., the opaque material 178. In accordance with certain examples, the substrate 2 may include a silicon wafer, such as 300-millimeter wafer. In certain examples the substrate 2 may include a blanket substrate, such as a blanket wafer. In accordance with certain examples, the substrate 2 may include a patterned substrate, such as a patterned wafer.

The susceptor support 162 is arranged within the lower chamber 176 of the chamber body 136 and along the rotation axis 180, and is fixed in rotation relative to the susceptor 160. The shaft member 170 is fixed in rotation relative to the susceptor support 162, extends through the lower chamber 176 and through the lower wall 154 of the chamber body 136, and couples the susceptor 160 to the drive module 144. The drive module 144 is operably connected to the susceptor 160 through the shaft member 170 and the susceptor support 162, and is configured to rotate the susceptor 160 about the rotation axis 180. In certain examples the drive module 144 may be operably associated with the controller 108 (shown in FIG. 1).

The plurality of lift pins 164 are slidably received within respective through-holes 168 defined in the susceptor 160 and have a retracted position 182 (shown in FIG. 3) and an extended position 184 (shown in FIG. 4). Each through-hole 168 extends between upper and lower surfaces of the susceptor 160, couples the upper surface of the susceptor to the lower surface of the susceptor 160, and is radially offset from the rotation axis 180. It is contemplated that the plurality of lift pins 164 be operably associated with a lift pin actuator 166. The lift pin actuator 166 is configured to drive the plurality of lift pins 164 upwards through the susceptor 160 from the retracted position 182 to the extended position 184 to unseat substrates, e.g., the substrate 2 (shown in FIG. 1), from the susceptor 160. It is contemplated that the plurality of lift pins 164 be rotatable relative to the lift pin actuator 166, the plurality of lift pins 164 rotating with the susceptor 160 about the rotation axis 180, and the plurality of lift pins 164 returning to the retracted position 182 from the extended position 184 by operation of gravity during lift pin actuator stroke.

The lift pin actuator 166 extends about the shaft member 170, is fixed rotation relative to the chamber body 136, and is translatable upwards and downwards relative to the shaft member 170 along the rotation axis 180 to drive each may be operably associated the controller 108 (shown in FIG. 1) to drive the plurality of lift pins 164 from the retracted position 182 upwards (i.e., opposite the direction of gravity) to the extended position 184 (shown in FIG. 4) during the lift pin actuator stroke. In certain examples, return of the plurality of lift pins 164 from the extended position 184 to the retracted position 182 may be accomplished translating the lift pin actuator 166 downwards relative to the shaft member 170, the plurality of lift pins 164 returning to the retracted position 182 by operation of gravity. In accordance with certain examples, the lift pin actuator 166 may be operably associated with the controller 108.

Referring to FIG. 4, it is contemplated that each of the plurality of lift pins 164 have a head portion 186 and a shank portion 188. The shank portion 188 is slidably received within one of the plurality of through-holes 168 extending through the susceptor 160. The head portion 186 of the lift pin 164 extends upwards from the shank portion 188 of the lift pin 164, is separated from the lift pin actuator 166 by the shank portion 188 of the lift pin 164, and is configured to engage an underside of the substrate 2 (shown in FIG. 1) during seating and unseating of the substrate 2 from the susceptor 160. In this respect it is contemplated that the head portion 186 be recessed in upper surface of the susceptor 160 such that the shank portion 188 is at least partially disposed in the lower chamber 176 of the chamber body 136 when the lift pin 164 is in the retracted position 182. When the lift pin 164 is in the extended position 184, the head portion 186 of the lift pin 164 is disposed in the upper chamber 174 of the chamber body 136. It is contemplated that the lift pin 164 be operably associated with the lift pin actuator 166 for movement between retracted position 182 and the extended position 184, e.g., the lift pin actuator 166 mechanically engaging an end of the lift pin 164 opposite the head portion 186 during the lift pin actuator stroke 196 as the lift pin actuator 166 drives the lift pin 164 upwards from the retracted position 182 to the extended position 184. In the illustrated example reactor 104 includes three (3) lift pins 164. However, as will be appreciated by those of skill in the art in view of the present disclosure, examples of the reactor 104 may have fewer than three (3) lift pins or more than three (3) lift pins and remain within the scope of the present disclosure.

Deposition of the film 4 (shown in FIG. 1) onto the substrate 2 (shown in FIG. 1) is accomplished by loading the substrate 2 into the upper chamber 174 of the chamber body 136, flowing a film precursor through the upper chamber 174 under conditions that cause the film 4 onto the upper surface 6 (shown in FIG. 1) of the substrate 2, and thereafter unloading the substrate 2 from the chamber body 136. Loading of the substrate 2 into the upper chamber 174 is in turn accomplished by cooperation of the lift pin 164 with a substrate handler 190 (shown in FIG. 1) and a gate valve 192 (shown in FIG. 1). In this respect the gate valve 192 couples the reactor 104 to the external environment and provides selective communication with the interior 146 of the chamber body 136. The substrate handler 190 is configured to load and unload the substrate 2 from the upper chamber 174 of the chamber body 136, and the lift pin 164 is configured to seat and unseat substrates from the upper surface of the susceptor 160 by movement between the retracted position 182 and the extended position 184. Seating of the substrate 2 is accomplished prior to deposition of the film 4 onto the substrate 2 and unseating of the substrate 2 from the susceptor 160 is accomplished after deposition of the film 4 onto the substrate 2.

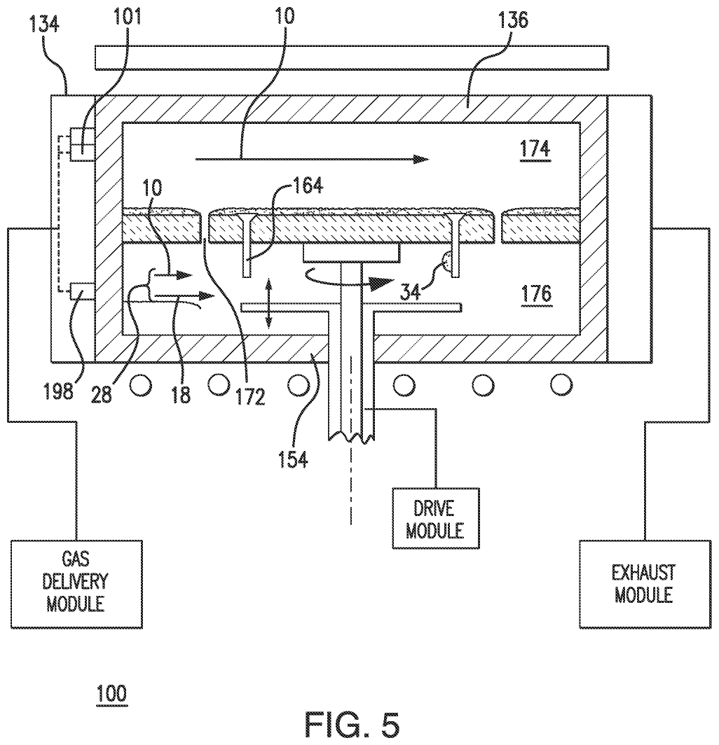

As will be appreciated by those of skill in the art in view of the present disclosure, the shank portion 188 of the lift pin 164 is exposed to substances that may diffuse into the lower chamber 176 from the upper chamber 174 through the aperture 172. Once in the lower chamber 176, the substances may cause material accumulation, e.g., a material accumulation 34 (shown in FIG. 5), on surfaces and/or structures in the lower chamber 176. Such material accumulation, when present in sufficient thickness and/or composition, may interfere with the operation of the reactor 104. For example, material accumulation on the interior surface of the lower wall 154 of the chamber body 136 may limit the ability of the lower lamp bank 142 to radiantly communicate heat into the chamber body 136 through the lower wall 154. Material accumulation on the shank portions 188 of the lift pin 164 may also cause the lift pins 164 to bind in the susceptor 160 during movement between the retracted position 182 and extended position 184. To limit such material accumulation, the semiconductor processing system 100 is configured to purge the lower chamber 176 with a purge flow including the etchant 10 (shown in FIG. 2) to remove, by etching, such material accumulations from surfaces and/or structures in the lower chamber 176 of the chamber body 136.

With reference to FIG. 5, the semiconductor processing system 100 is shown with the lower chamber 176 of the chamber body 136 being purged with a first purge flow 28 including the etchant 10 while the upper chamber 174 of the chamber body 136 is etched. Etching of upper chamber 174 is accomplished by flowing an etchant, e.g., the etchant 10, into the upper chamber 174 from the etchant source 110 using the injection flange 134. Purging of the lower chamber 176 is accomplished by flowing the first purge flow 28 to the lower chamber 176 of the chamber body 136 using the injection flange 134. It is contemplated that the first purge flow 28 include the etchant 10, which may be provided by the etchant source 110 (shown in FIG. 2). In certain examples the etchant 10 may include a halide, such as chlorine. In accordance with certain examples, the etchant 10 may include hydrochloric acid (HCl). It also contemplated that, in accordance with certain examples, that the first purge flow 28 may include a carrier/purge gas, e.g., the carrier/purge gas 18. The carrier/purge gas may be provided by the carrier/purge gas source 116 (shown in FIG. 2), and may consist of (or consist essentially of) hydrogen (H₂) gas.

As will be appreciated by those of skill in the art in view of the present disclosure, etching the upper chamber 174 of the chamber body 136 may beneficially decompose substances deposited on surfaces and structures in the upper chamber 174, such residual precoating and films deposited in the upper chamber 174 during a prior deposition operation. As will also be appreciated by those of skill in the art in view the present disclosure, decomposition products generated during the etching may, during some etching operations, diffuse into the lower chamber 176 through the aperture 172. Once in the lower chamber 176 the decomposition products may condense and/or participate in reactions, potentially causing material accumulations, e.g., the material accumulation 34, to develop on surfaces and/or structures in the lower chamber 176. It is contemplated that the etchant 10 included in the first purge flow 28 etch surfaces and structures in the lower chamber 176 during etching of the upper chamber 174, limiting (or preventing entirely) such material accumulation in the lower chamber 176. As will be appreciated by those of skill in the art in view of the present disclosure, limiting (or preventing) material accumulation on surfaces and/or structures in the lower chamber 176 limit the affect that the material accumulation could otherwise having on operation of the reactor 104, for example, by limiting transmissivity reduction of the lower wall 154 and/or resistance to movement of the lift pins 164 otherwise associated with material accumulation on surfaces and structures in the lower chamber 176.

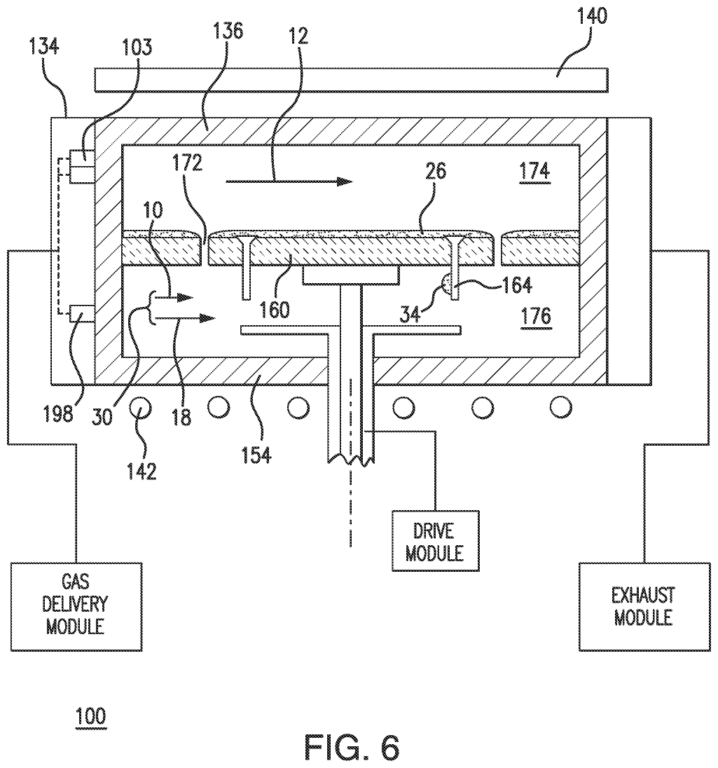

With reference to FIG. 6, the semiconductor processing system 100 is shown with the lower chamber 176 being purged using a second purge flow 30 while a precoat 26 is deposited in the upper chamber 174 of the chamber body 136. Deposition of the precoat 26 is accomplished by heating the susceptor 160 to a predetermined precoating temperature, providing a flow of the precoat precursor 12 to the chamber body 136, and flowing the precoat precursor 12 through the upper chamber 174 such that the precoat 26 deposited onto an upper surface of the susceptor 160. Heating the susceptor 160 to the predetermined precoating temperature may be accomplished using the upper lamp bank 140 and/or the lower lamp bank, 142. Provision of the precoat precursor 12 to the upper chamber 174 may be accomplished using the injection flange 134. In certain examples, the precoat precursor 12 may be provided a deposition header 103 located in the injection flange 134 and fluidly coupling the precoat precursor source 112 (shown in FIG. 2) to the upper chamber 174.

Once the precoat 26 reaches a desired thickness, flow of the precoat precursor 12 ceases and a substrate, e.g., the substrate 2 (shown in FIG. 1) may thereafter be loaded for film deposition onto the substrate. Advantageously, deposition of the precoat 26 face of the susceptor 160 can limit bridging between the substrate 2 and the susceptor 160 during deposition of the film 4 (shown in FIG. 1) onto the substrate 2, enabling the deposition of a thick epitaxial film onto the upper surface 6 (shown in FIG. 1) of the substrate 2. For example, the film 4 may have a thickness that is between about 25 microns and about 120 microns, or between about 50 microns and 100 microns, or even between about 70 microns and about 90 microns.

As will be appreciated by those of skill in the art in view of the present disclosure, residual precoat precursor and/or reaction products associated with precoating the upper chamber 174 may, in some precoating operation, diffuse into the lower chamber 176 of the chamber body 136. For example, residual precoat precursor and/or reaction products may diffuse from the upper chamber 174 through the aperture 172 and into the lower chamber 176. Once in the lower chamber 176 the residual precoat precursor and/or reaction products may cause material accumulation, e.g., the material accumulation 34, on surfaces and/or structures in the lower chamber 176. Since such material accumulation on surfaces and/or structures in the lower chamber 176 can also limit reliability of the reactor 104, for example, by reducing transmissivity of the lower wall 154 of the chamber body 136 and/or impairing movement of the lift pins 164 during movement between the retracted position 182 (shown in FIG. 3) and the extended position 184 (shown in FIG. 4), the etchant 10 is also included in the second purge flow 30.

Purging of the lower chamber 176 with the second purge flow 30 is accomplished by providing a flow of the carrier/purge gas 18 and a flow of the etchant 10 to the reactor 104. For example, flows the carrier/purge gas 18 and the etchant 10 may be provided to the injection flange 134 and communicated to the lower chamber 176 through the lower chamber purge header 198. Once in the lower chamber 176, the etchant 10 limit (or prevents) material accumulation on surfaces and/or structures in the lower chamber 176 that otherwise could occur during the precoating of the upper chamber 174 in certain precoating operations.

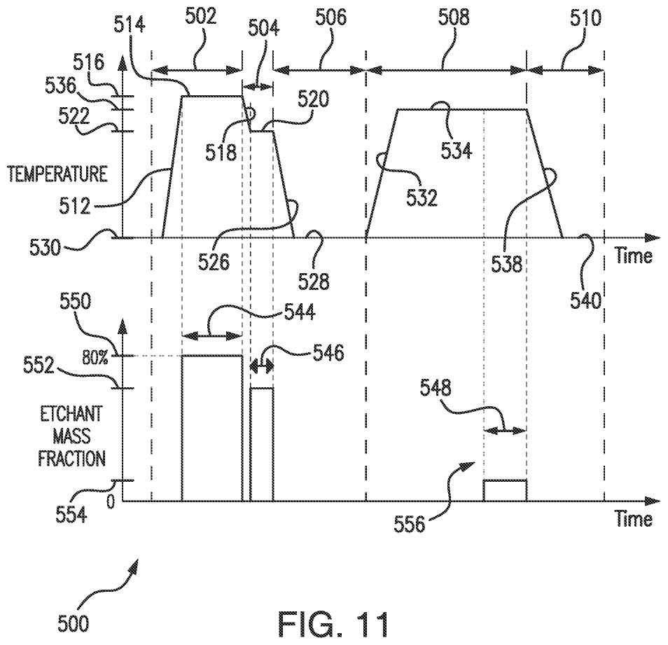

Without being bound by a particular theory or mode of operation, it is believed the that the etchant 10 included in the second purge flow 30 may etch surfaces and structures within the lower chamber 176. In this respect it is contemplated that the etchant 10 be included in the second purge flow 30 at a second etchant mass fraction, e.g., the second etchant mass fraction 552 (shown in FIG. 11), sufficient to remove material accumulation in real-time with formation of the material accumulation. The balance of the second purge flow 30 may consist of (or consist essentially of) the carrier/purge gas 18, the lower chamber purge header 198 further coupling the carrier/purge gas source 116 (shown in FIG. 2) to the lower chamber 176 is this respect. In certain examples, the etchant 10 may be included in the second purge flow 30 continuously during the precoating of the upper chamber 174, e.g., inclusion of the etchant 10 starting and ceasing at substantially the same time as flow of the precoat precursor 12. In accordance with certain examples, the etchant may be included in the second purge flow 30 discontinuously during the precoating of the upper chamber 174. In this respect inclusion of the etchant 10 in the second purge flow 30 start and/or cease at different times than the start and cessation of the precoat precursor 12, limiting exposure of chamber components to the etchant 10. In further examples, the second etchant mass fraction may be less than the first etchant mass fraction, also limiting exposure of chamber components to the etchant 10.

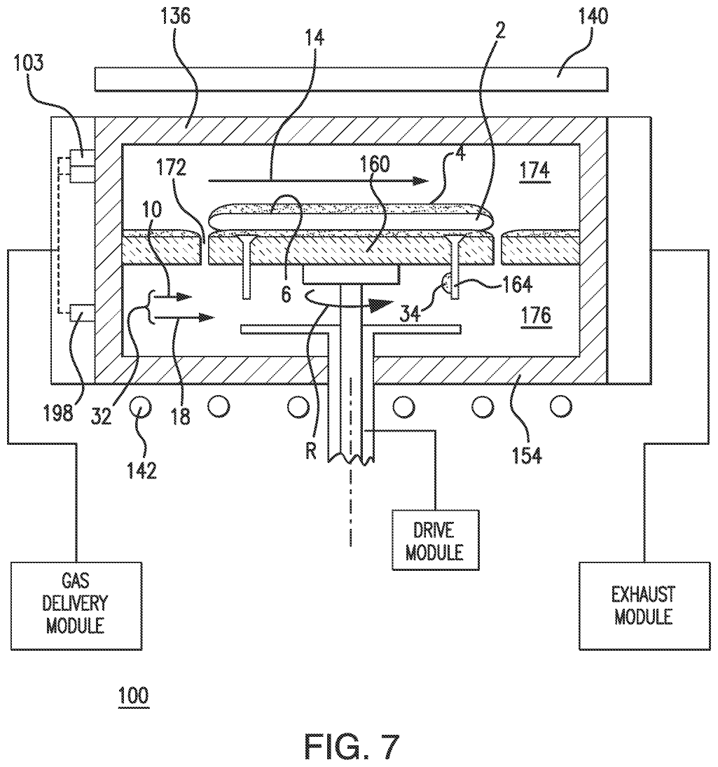

With reference to FIG. 7, the semiconductor processing system 100 is shown with the lower chamber 176 being purged using a third purge flow 32 while the film 4 is deposited onto the substrate 2 in the upper chamber 174 of the chamber body 136. Deposition of the film 4 is accomplished by heating the susceptor 160 to a predetermined deposition temperature, providing a flow of the film precursor 14 to the chamber body 136, and flowing the film precursor 14 through the upper chamber 174 such that the film 4 deposits onto the upper surface 6 of the substrate 2. Heating the susceptor 160 to the predetermined deposition temperature may be accomplished using the upper lamp bank 140 and/or the lower lamp bank 142. Provision of the film precursor 14 to the upper chamber 174 may be accomplished using the injection flange 134. In certain examples, the film precursor 14 may be provided to the deposition header 103 fluidly coupling the film precursor source 114 (shown in FIG. 2) to the upper chamber 174 of the chamber body 136. Once the film 4 reaches a desired thickness, flow of the film precursor 14 to the chamber body 136 ceases.

As will be appreciated by those of skill in the art in view of the present disclosure, residual film precursor and/or reaction products associated with film deposition onto the substrate 2 in the upper chamber 174 may, in some film deposition operations, diffuse into the lower chamber 176. For example, residual film precursor and/or reaction products may diffuse from the upper chamber 174 through the aperture 172 and into the lower chamber 176. Once in the lower chamber 176 the residual film precursor and/or reaction products may cause material accumulation, e.g., the material accumulation 34, on surfaces and/or structures in the lower chamber 176. Since such material accumulation on surfaces and/or structures in the lower chamber 176 can further limit reliability of the reactor 104 by reducing transmissivity of the lower wall 154 of the chamber body 136 and/or impairing movement of the lift pins 164 during movement between the retracted position 182 (shown in FIG. 3) and the extended position 184 (shown in FIG. 4), the etchant 10 is further included in the third purge flow 32.

Purging of the lower chamber 176 with the third purge flow 32 is accomplished by providing a flow of the carrier/purge gas 18 and a flow of the etchant 10 to the reactor 104. For example, flows the carrier/purge gas 18 and the etchant 10 may be provided to the injection flange 134 and communicated to the lower chamber 176 through the lower chamber purge header 198. Once in the lower chamber 176, the etchant 10 limit (or prevents) material accumulation on surfaces and/or structures in the lower chamber 176 that otherwise could occur during the precoating of the upper chamber 174 in certain precoating operations.

Without being bound by a particular theory or mode of operation, it is believed the that the etchant 10 included in the second purge flow 30 may etch surfaces and structures within the lower chamber 176 to remove material accumulation prior to completion of the deposition operation. In this respect it is contemplated that the etchant 10 be included in the third purge flow 32 at a third etchant mass fraction, e.g., the third etchant mass fraction 554 (shown in FIG. 11), sufficient to remove material accumulation in real-time with formation of the material accumulation. The balance of the third purge flow 32 may consist of (or consist essentially of) the carrier/purge gas 18, the lower chamber purge header 198 further fluidly coupling the carrier/purge gas source 116 (shown in FIG. 2) to the lower chamber 176 is this respect. In certain examples, the etchant 10 may be included in the third purge flow 32 continuously during deposition of the film 4 onto the substrate 2 in the upper chamber 174. In accordance with certain examples, the etchant 10 may be included in the third purge flow 32 discontinuously during the precoating of the upper chamber 174. In this respect the etchant 10 may be included in the third purge flow 32 during only a portion of the interval during which the film 4 is deposited onto the substrate 2 in the upper chamber 174, for example, during only a terminal portion of the film deposition interval. As will be appreciated by those of skill in the art in view of the present disclosure, this can limit etching of the film 4 by the etchant 10, limiting edge thickness variation potentially associated with inclusion of the etchant 10 in the third purge flow 32. In further examples, the third etchant mass fraction may be less than the second etchant mass fraction, further limiting exposure of chamber components to the etchant 10.

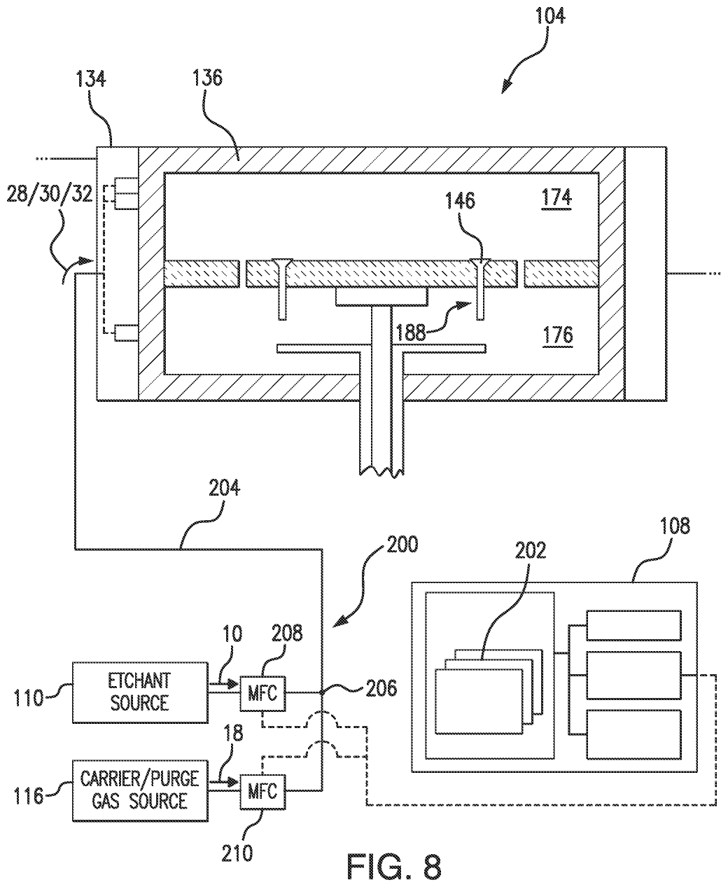

With reference to FIG. 8, a lower chamber etchant purge kit 200 is shown. The lower chamber etchant purge kit 200 includes a computer program product 202, an etchant conduit 204, and a tee fitting 206. The lower chamber etchant purge kit 200 also includes an etchant MFC 208 and a carrier/purge gas MFC 210. The computer program product 202 includes a non-transitory memory having instructions recorded in the plurality of program modules that, when read by the controller 108, cause the controller 108 execute certain operations. Among the operations are operations to (a) purge the lower chamber 176 of the chamber body 136 with the first purge flow 28 including the etchant 10 using the etchant MFC 208 while etching the upper chamber 174 of the chamber body 136, (b) purge the lower chamber 176 of the chamber body 136 with the second purge flow 30 including the etchant 10 using the etchant MFC 208 while depositing the precoat 26 in the upper chamber 174 of the chamber body 136, and (c) purge the lower chamber 176 of the chamber body 136 with a third purge flow 32 including the etchant 10 using the etchant MFC 208 while depositing the film 4 (shown in FIG. 1) onto the substrate 2 (shown in FIG. 1) seated in the upper chamber 174 of the chamber body 136.

The etchant conduit 204 is configured to fluidly couple the etchant source 110 to the lower chamber 176 of the chamber body 136. In the illustrated example, the etchant conduit 204 is fluidly coupled to the lower chamber 176 by the injection flange 134. More specifically, the etchant conduit 204 and the etchant MFC 208 fluidly couple the etchant source 110 to the tee fitting 206, the carrier/purge gas MFC fluidly couples the carrier/purge gas source 116 to the tee fitting 206, the tee fitting 206 fluidly couples the carrier/purge gas source 116 to the injection flange 134, and the etchant source 110 and the carrier/purge gas source 116 are both fluidly coupled to the lower chamber 176 of the chamber body 136 through the tee fitting 206 and the injection flange 134 to selectively purge the lower chamber 176 with a purge flow including the etchant 10, e.g., one or more of the purge flows 28-32, at a mass fraction controlled using the etchant MFC 208. As will be appreciated by those of skill in the art in view of the present disclosure, purging the lower chamber 176 through the injection flange 134 can simplify retrofit of existing reactors in examples where the injection flange connected to the chamber body is arranged to provide the purge flow to the lower chamber of the chamber body.

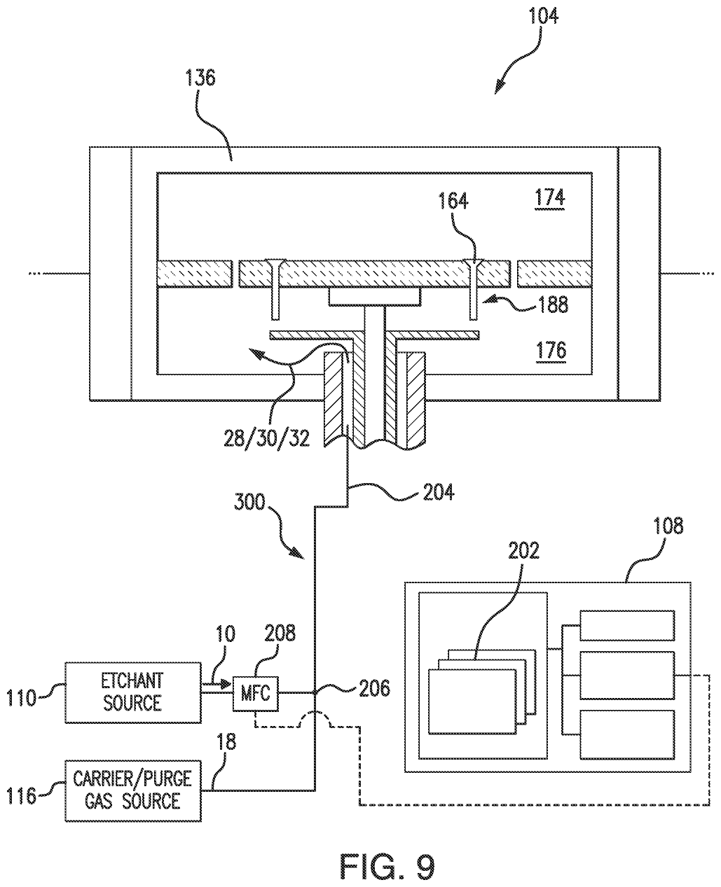

With reference to FIG. 9, a lower chamber etchant purge kit 300 is shown. The lower chamber etchant purge kit 300 is similar to the lower chamber etchant purge kit 200 (shown in FIG. 8) and is additionally configured to purge the lower chamber 176 of the chamber body 136 through the tube member 194. In this respect the etchant conduit 204 and the etchant MFC 208 fluidly couple the etchant source 110 to the tee fitting 206, the tee fitting 206 fluidly couples the carrier/purge gas source 116 to the tube member 194, and the etchant source 110 and the carrier/purge gas source 116 are both fluidly coupled to the lower chamber 176 of the chamber body 136 through the tee fitting 206 and the tube member 194 to selectively purge the lower chamber 176 with a purge flow including the etchant 10, e.g., one or more of the purge flows 28-32, at a mass fraction controlled using the etchant MFC 208. As will be appreciated by those of skill in the art in view of the present disclosure, issuing the purge flow into the lower chamber 176 through the tube member 194 limits the distance over which the etchant 10 otherwise may need to diffuse through to reach the lift pin 164. This increases etching accomplished by the etchant per unit mass fraction of the etchant included in the purge flows, limiting the amount of the etchant otherwise required to suppress (or eliminate) material accumulation on shank portions 188 of the lift pins 164.

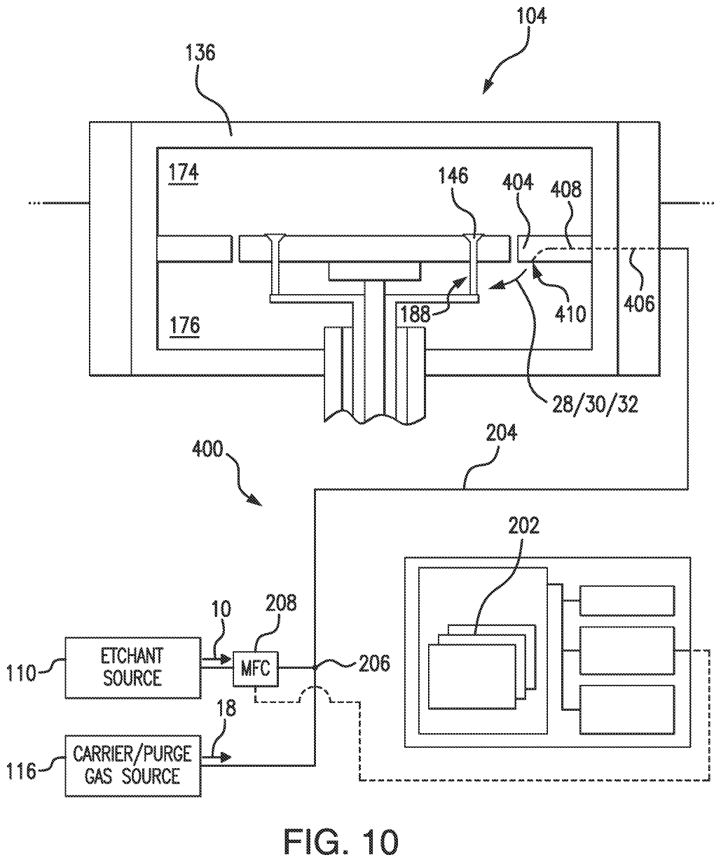

With reference to FIG. 10 a lower chamber etchant purge kit 400 is shown. The lower chamber etchant purge kit 400 is similar to the lower chamber etchant purge kit 200 (shown in FIG. 8), additionally includes an exhaust flange 402 and a divider 404, and is further configured to purge the lower chamber 176 of the chamber body 136 through the exhaust flange 402 and the divider 404. In this respect the exhaust flange 402 has an exhaust flange etchant channel 406 fluidly coupling the etchant conduit 204 the divider 404, the divider 404 has a divider etchant channel 408 and an etchant outlet 410 fluidly coupling the exhaust flange etchant channel 406 to the etchant outlet 410, and the etchant outlet 410 is configure to issue the a including an etchant, e.g., one or more of the purge flows 28-32, into the lower chamber 176 using the etchant MFC 208 at a location proximate the lift pin 164. As will be appreciated by those of skill in the art in view of the present disclosure, providing the purge flow at a location proximate the lift pin 164 limits the distance within the lower chamber 176 that the etchant need diffuse through to reach the shank portion 188 of the lift pin 164. This also increases etching accomplished by the etchant 10 per unit mass fraction of the etchant included in the purges flow, limiting the amount of the etchant otherwise required to suppress (or eliminate) material accumulation on the shank portion 188 of the lift pin 164.

With reference to FIG. 11, a chart pair illustrating temperature and etchant mass fraction during an example of a deposition cycle 500 using the semiconductor processing system 100 (shown in FIG. 1) is shown. In the illustrated example the deposition cycle 500 includes an etching operation 502, a precoating operation 504, and a substrate loading operation 506. The precoating operation 504 occurs after the etching operation 502 and the substrate loading operation 506 occurs after the precoating operation 504. In the illustrated example the deposition cycle 500 also includes a deposition operation 508 and a substrate unloading operation 510. It is contemplated that the deposition operation 508 occur after the substrate loading operation 506 and that the substrate unloading operation 510 occur after the deposition operation 508. Deposition cycle 500 may be one of a plurality of deposition cycles 500 performed sequentially by the semiconductor processing system 100 to deposit films onto substrates.

During the etching operation 502 surfaces and structures in the upper chamber 174 (shown in FIG. 3) are etched using an etchant, e.g., the etchant 10 (shown in FIG. 2). The etchant may be provided to the upper chamber 174 by the gas delivery module 102 (shown in FIG. 1). During the precoating operation 504, interior surfaces and structures in the upper chamber 174 are precoated using a precoat precursor, e.g., the precoat precursor 12 (shown in FIG. 2), which is provided to the upper chamber 174 by the gas delivery module 102. During the deposition operation 508, a film is deposited onto the upper surface of a substrate, e.g., the film 4 (shown in FIG. 1) deposited onto the upper surface 6 (shown in FIG. 1) of the substrate 2 (FIG. 1), using a film precursor, e.g., the film precursor 14 (shown in FIG. 2), which also may be provided to the upper chamber 174 by the gas delivery module 102. During the substrate loading operation 506 and the substrate unloading operation 510 no etchant may be included in purge flows provided to the lower chamber, and the purge flows themselves may cease at least in part. Although shown and described herein as including specific operations, it is to be understood and appreciated that the deposition cycle 500 may include fewer or additional operations, or another ordering of operations, and remain within the scope of the present disclosure.

The etching operation 502 includes an etch temperature ramping segment 512 and an etching segment 514. During the etch temperature ramping segment 512, temperature of the susceptor 160 (shown in FIG. 3) is ramped to a predetermined etching temperature 516. During the etching segment 514, temperature of the susceptor 160 is maintained at the predetermined etching temperature 516 and etchant flowed through the upper chamber 174 of the chamber body 136. It is contemplated that the etchant decompose material accumulations within the upper chamber 174, e.g., residual precoating and/or films, deposited therein during the prior deposition cycle or cycles. As will be appreciated by those of skill in the art in view of the present disclosure, this the upper chamber 174 for depositing the precoat 26 (shown in FIG. 6) therein.

The precoating operation 504 follows the etching operation 502 and includes a precoat temperature ramping segment 518 and a precoating segment 520. During the precoat temperature ramping segment 518 temperature of the susceptor 160 (shown in FIG. 3) is ramped to a predetermined precoating temperature 522. During the precoating segment 520, temperature of the susceptor 160 is maintained at the predetermined precoating temperature 522 and the precoat precursor 12 (shown in FIG. 2) provided to the upper chamber 174 (shown in FIG. 3). As the precoat precursor flows through the upper chamber 174 a precoat, e.g., the precoat 26 (shown in FIG. 6), is deposited within the upper chamber 174. As will be appreciated by those of skill in the art in view of the present disclosure, precoating the upper chamber 174 reduces the likelihood of damage to surfaces and structures within the chamber body 136 (shown in FIG. 3), e.g., the lift pins 164 (shown in FIG. 3), during the subsequent substrate loading operation and/or substrate unloading operation. For example, the precoat 26 may limit (eliminate) bridging formation between the substrate and the susceptor seating the substrate during the deposition operation 508. In certain examples the predetermined precoating temperature 522 may be lower than the predetermined etching temperature 516. In accordance with certain examples, the precoat 26 may be deposited onto an upper surface of the susceptor 160, such as using a silicon-containing precursor like dichlorosilane (DCS).

The substrate loading operation 506 follows the precoating operation 504 and includes chamber cooling segment 526 and a substrate loading segment 528. During the chamber cooling segment 526, the chamber body 136 is cooled to a predetermined loading temperature 530. Once the chamber body 136 reaches the predetermined loading temperature 530 the substrate loading segment 528 executes, the gate valve 192 (shown in FIG. 1) opening and a substrate, e.g., the substrate 2 (shown in FIG. 1), transferred into the upper chamber 174 using the substrate transfer robot 189 (shown in FIG. 1). The substrate is thereafter seated on the susceptor 160 by moving the lift pins 164 to their respective extended position 184, transferring the substrate 2 to the lift pin 164, and thereafter moving the lift pins 164 to their respective retracted position 182. As will be appreciated by those of skill in the art in view of the present disclosure, this seats the substrate 2 on the susceptor 160.

The deposition operation 508 follows the substrate loading operation 506 and includes a deposition temperature ramping segment 532 and a film deposition segment 534. During the deposition temperature ramping segment 532, temperature of the susceptor 160 (shown in FIG. 3) and the substrate 2 (shown in FIG. 1) is ramped to a predetermined film deposition temperature 536. During the film deposition segment 534, temperature of the susceptor 160 is maintained at the predetermined film deposition temperature 536 and a film precursor, e.g., the film precursor 14 (shown in FIG. 2), provided to the upper chamber 174 (shown in FIG. 3). It is contemplated that the film precursor 14 cause a film, e.g., the film 4 (shown in FIG. 1), to be deposited onto the substrate 2. In certain examples, the predetermined film deposition temperature 536 may be greater than the predetermined precoating temperature 522. In accordance with certain examples, the predetermined film deposition temperature 536 may be lower than the predetermined etching temperature 516. It is also contemplated that, in accordance with certain examples, the predetermined film deposition temperature 536 may be lower than both the predetermined etching temperature 516 and greater than the predetermined precoating temperature 522. As will be appreciated by those of skill in the art in view of the present disclosure, such temperature relationships can limit the amount of etchant required to etch the lower chamber 176 (shown in FIG. 3), limiting damage to chamber components otherwise potentially associated with exposure to the etchant 10.

The substrate unloading operation 510 includes a chamber cooling segment 538 and a substrate unloading segment 540. During the chamber cooling segment 538, the chamber body 136 (shown in FIG. 3) is cooled to a predetermined unloading temperature 542, which may be substantially equivalent to the predetermined loading temperature 530. Once the chamber body 136 reaches the predetermined unloading temperature 542 the substrate unloading segment 540 executes. In this respect the lift pins 164 (shown in FIG. 3) move from their respective retracted position 182 (shown in FIG. 3) to their respective extended position 184 (shown in FIG. 4) to unseat the substrate 2 from the susceptor 160. The gate valve 192 (shown in FIG. 1) may thereafter open such that the substrate transfer robot 189 (shown in FIG. 1) may the substrate from 2 the upper chamber 174 (shown in FIG. 3) of the chamber body 136. The lift pins 164 may thereafter return to their respective retracted position 182. In certain examples return of the lift pins 164 to the retracted position 182 is accomplished by operation of gravity.

As has been explained above, material accumulations may form on surfaces and structures in the lower chamber 176 (shown in FIG. 3) of the chamber body 136 (shown in FIG. 3) during the deposition cycle 500. For example, decomposition products generated in the upper chamber 174 (shown in FIG. 3) during the etching operation 502 may, in some etching operations, diffuse into the lower chamber 176 of the chamber body 136. Once in the lower chamber 176, the decomposition products may condense and/or participate in a reactions that causes material accumulations in the lower chamber 176 of the chamber body 136. Residual precoating precursor and/or reaction products associated with the precoating operation 504 in the upper chamber 174 may, in some precoating operations, diffuse into the lower chamber 176 of the chamber body 136. Once in the lower chamber 176, the residual precursor and/or reaction products may also (or alternatively) condense and/or participate in reactions, also causing material accumulations in the lower chamber 176 of the chamber body 136. And residual film precursors and/or reaction products associated with the deposition operation 508 in the upper chamber 174 may, in some deposition operations, further (or alternatively) diffuse into the lower chamber 176, condense and/or participate in chemical reactions, and further cause material to accumulate within the lower chamber 176. Since such material accumulations can limit the reliability of the reactor 104 (shown in FIG. 1), e.g., by accumulating on the shank portion 188 (shown in FIG. 3) on one or more of the plurality of lift pins 164, potentially interfering with either (or both) the substrate loading operation 506 and the substrate unloading operation 510, it is contemplated that the lower chamber 176 of the chamber body 136 be purged with a purge flow including an etchant 10 during the deposition cycle 500. In the illustrated example, the deposition cycle 500 includes a first lower chamber etching operation 544, a second lower chamber etching operation 546, and a third lower chamber etching operation 548.

During the first lower chamber etching operation 544 the lower chamber 176 (shown in FIG. 3) is purged with the first purge flow 28 (shown in FIG. 5) including the etchant 10 (shown in FIG. 2). It is contemplated that the etchant 10 provided to the lower chamber 176 in the first purge flow 28 etch surfaces and structures in the lower chamber 176, e.g. substantially in real-time with the material accumulation on surfaces and/or structures in the lower chamber 176, as decomposition products diffuse into the lower chamber 176 during the first lower chamber etching operation 544. In certain examples, the etchant 10 may be provided to the lower chamber 176 continuously during the etching segment 514 of the etching operation 502. In accordance with certain examples, the etchant 10 may be provided to the lower chamber 176 discontinuously during the etching segment 514 of the etching operation 502. As will be appreciated by those of skill in the art in view of the present disclosure, providing the etchant 10 to the lower chamber 176 discontinuously during the etching segment 514 can limit damage to chamber components otherwise associated with exposure to the etchant 10. As will also be appreciated by those of skill in the art in view of the present disclosure, providing the etchant 10 continuously to the lower chamber 176 during the etching segment 214 of the etching operation 502 may remove substantially all material accumulation remains within the lower chamber 176, preventing the material from otherwise hardening (and thereby being more difficult to remove) due the quenching effect that subsequent temperature change could otherwise have on the accumulated material.

During the second lower chamber etching operation 546, the lower chamber 176 (shown in FIG. 3) is purged with the second purge flow 30 (shown in FIG. 6) including the etchant 10 (shown in FIG. 2). It is contemplated that the etchant 10 provided to the lower chamber 176 in the second purge flow 30 also etch surfaces and/or structures in the lower chamber 176, e.g., the shank portions 188 of the lift pins 164. As above, the etching removes material accumulation on the surfaces and/or structures substantially in real-time with material accumulation in the lower chamber 176 otherwise associated with diffusion of residual precoat precursor and/or reaction products from the upper chamber 174 (shown in FIG. 3) into the lower chamber 176 during deposition of the precoat 26 (shown in FIG. 6). In certain examples, the etchant 10 may be provided to the lower chamber 176 continuously during the precoating segment 520 of the precoating operation 504. In accordance with certain examples, the etchant 10 may be provided to the lower chamber 176 discontinuously during the precoating segment 520 of the precoating operation 504. As will be appreciated by those of skill in the art in view of the present disclosure, providing the etchant 10 to the lower chamber 176 discontinuously during the precoating segment 520 can limit damage to chamber components within the lower chamber 176 otherwise associated with exposure to the etchant 10. As will also be appreciated by those of skill in the art in view of the present disclosure, providing the etchant 10 continuously to the lower chamber 176 during the precoating segment 520 may ensure that little (or none) of the accumulated material remains during the subsequent chamber cooling segment 526 and deposition temperature ramping segment 532, limiting the quenching and annealing effect that the temperature changes during the segment could otherwise have on the accumulated material.

During the third lower chamber etching operation 548 the lower chamber 176 (shown in FIG. 3) is purged with the third purge flow 32 (shown in FIG. 7) including the etchant 10 (shown in FIG. 2). It is contemplated that the etchant 10 provided to the lower chamber 176 in the third purge flow 32 further etch surfaces and structures in the lower chamber 176, e.g., the shank portions 188 (shown in FIG. 3) of the lift pins 164 (shown in FIG. 3), removing material accumulation within the lower chamber 176 associated with diffusion of residual film precursor and/or reaction products from the upper chamber 174 (shown in FIG. 3) into the lower chamber 176 during deposition of the film 4 (shown in FIG. 1) onto the substrate 2 (shown in FIG. 1). In certain examples, the etchant 10 may be provided to the lower chamber 176 continuously during the film deposition segment 534. In accordance with certain examples, the etchant 10 may be provided to the lower chamber 176 discontinuously during the film deposition segment 534. As will be appreciated by those of skill in the art in view of the present disclosure, providing the etchant 10 to the lower chamber 176 discontinuously during the film deposition segment 534 can limit damage to chamber components within the lower chamber 176 otherwise associated with exposure to the etchant 10. As will also be appreciated by those of skill in the art in view of the present disclosure, providing the etchant 10 continuously to the lower chamber 176 during the film deposition segment 534 can ensure that little (or none) of the accumulated material is in place during the subsequent chamber cooling segment 538 and substrate unloading segment 540, limiting the quenching effect the temperature change could otherwise have on the crystalline structure of the residual material accumulation in the lower chamber 176.

In certain examples, mass fraction of the etchant 10 (shown in FIG. 2) provided to the lower chamber 176 (shown in FIG. 3) during one or more of the segments of the deposition cycle 500 may differ from a mass fraction of the etchant provided during another of the segments of the deposition cycle 500. In this respect it is contemplated that the etchant 10 be provided to the lower chamber 176 as a first etchant mass fraction 550 included in the first purge flow 28 (shown in FIG. 5) during the etching operation 502, that the etchant 10 be provided to the lower chamber 176 as a second etchant mass fraction 552 included in the second purge flow 30 (shown in FIG. 6) during the precoating operation 504, and that the etchant 10 be provided to the lower chamber 176 as a third etchant mass fraction 554 included in the third purge flow 32 (shown in FIG. 7) during the deposition operation 508. In the illustrated example, the second etchant mass fraction 552 is less than the first etchant mass fraction 550 and the third etchant mass fraction 554 is less than second etchant mass fraction 552. As will be appreciated by those of skill in the art in view of the present disclosure, this matches mass flow of the etchant with the rate at which material accumulates on surfaces and/or structures in the lower chamber 176 due to the operation occurring upper chamber 174 of the chamber body 136, reducing both risk of lift pin binding due to material accumulation as well as limiting exposure of chamber components to the etchant 10 included in the purge flows 28-32 (shown in FIGS. 5-7). For example, the etchant mass fractions 552-556 may be between about 0% and about 80% of the total mass flow of the purge flows provided to the lower chamber 176 during the etching operation 502, the precoating operation 504, and the deposition operation 508.

In certain examples, the etchant 10 (shown in FIG. 2) may be provided to the lower chamber 176 (shown in FIG. 3) in the third purge flow 32 (shown in FIG. 7) during only a terminal portion 556 of the film deposition segment 534 of the deposition operation 508. For example, the etchant 10 may be provided to lower chamber 176 during less than a terminal 50% of the film deposition segment 534, or less than a terminal 40% of the film deposition segment 534, or even less than a terminal 30% of the film deposition segment 534. As will be appreciated by those of skill in the art in view of the present disclosure, in addition to limiting exposure of chamber components to the etchant 10, this can further limits etching of the film 4 deposited onto the upper surface 6 of the substrate 2 in the upper chamber 174 while also limiting (or eliminating) material accumulation in the lower chamber 176 of the chamber body 136 (shown in FIG. 3) during the deposition operation 508.

With reference to FIGS. 12-16, a film deposition method 600 is shown according to an example of the present disclosure. Referring to FIG. 12, the film deposition method 600 includes etching an upper chamber of a reactor and precoating the upper chamber of the reactor, e.g., the upper chamber 174 (shown in FIG. 3) of the reactor 104 (shown in FIG. 1), as shown with box 610 and box 620. The film deposition method 600 also includes loading a substrate , e.g., loading the substrate 2 (shown in FIG. 1), into the upper chamber of the reactor, as shown with box 630. The film deposition method 600 further includes depositing a film onto the substrate, e.g., the film 4 (shown in FIG. 1), and thereafter unloading the substrate from the upper chamber of the reactor, as shown with box 640 and box 650. In certain examples, films may be accomplished sequentially onto substrates by etching and precoating the upper chamber between film deposition operations, as shown with arrow 660. In the illustrated example precoating 620 follows the etching 610, substrate loading 630 follows precoating 620, deposition 640 follows the substrate loading 630, and substrate unloading 650 follows deposition 640. As will be appreciated by those of skill in the art in view of the present disclosure, the film deposition operation can include fewer or additional operations, or have a different operation order, and remain within the scope of the present disclosure.

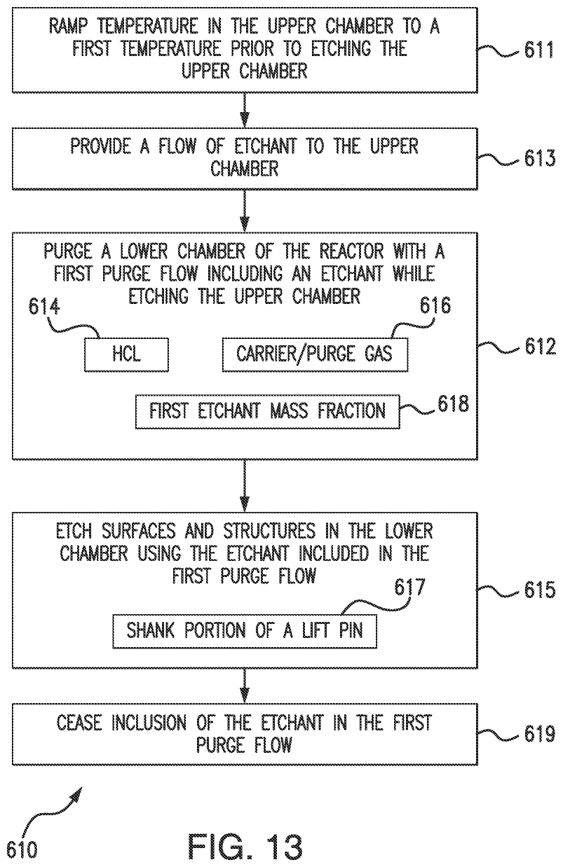

Referring to FIG. 13, it is contemplated that a lower chamber of the reactor, e.g., the lower chamber 176 (shown in FIG. 3) be purged with a first purge flow including an etchant, e.g., the first purge flow 28 (shown in FIG. 5), including the etchant 10 (shown in FIG. 1), while the upper chamber is etched, as shown with box 612. In certain examples, the etchant may include hydrochloric acid (HCl), as shown with box 614. In accordance with certain examples, the first purge flow may include a carrier/purge gas, e.g., the carrier/purge gas 18 (shown in FIG. 2), which may consist of (consist essentially) of hydrogen (H₂) gas, as shown with box 616. It is also contemplated that, in accordance with certain examples, the etchant included in the first purge flow may form a first etchant mass fraction of the first purge flow, e.g., the first etchant mass fraction 550 (shown in FIG. 11), as shown with box 618. The first etchant mass fraction included in the first purge flow may be between about 0% and about 80% of the first purge flow during the etching of the upper chamber.

As shown with box 611, etching the upper chamber may include ramping temperature in the upper chamber to a first temperature, e.g., the predetermined etching temperature 516 (shown in FIG. 11). For example, the susceptor 160 (shown in FIG. 3) may be heated using thermal energy communicated into the chamber body 136 (shown in FIG. 3) using the upper lamp bank 140 (shown in FIG. 3) and/or the lower lamp bank 142 (shown in FIG. 3) to ramp temperature in the upper chamber to the first temperature. As shown with box 613, a flow of the etchant, e.g., hydrochloric acid (HCl), may be provided to the upper chamber once temperature in the upper chamber reaches the first temperature. It is contemplated that surfaces and/or structures in the lower chamber be etched using the etchant included in the first purge flow during etching of the upper chamber, as shown with box 615. In this respect shank portions of lift pins disposed in the lower chamber may be etched by the etchant included in the first purge flow during the etching of the upper chamber, e.g., the shank portion 188 (shown in FIG. 3) of the lift pin 164 (shown in FIG. 3), as shown with box 617. It is contemplated that flow of the etchant into the lower chamber using the first purge flow cease once etching of the upper chamber is done, as shown with box 619.

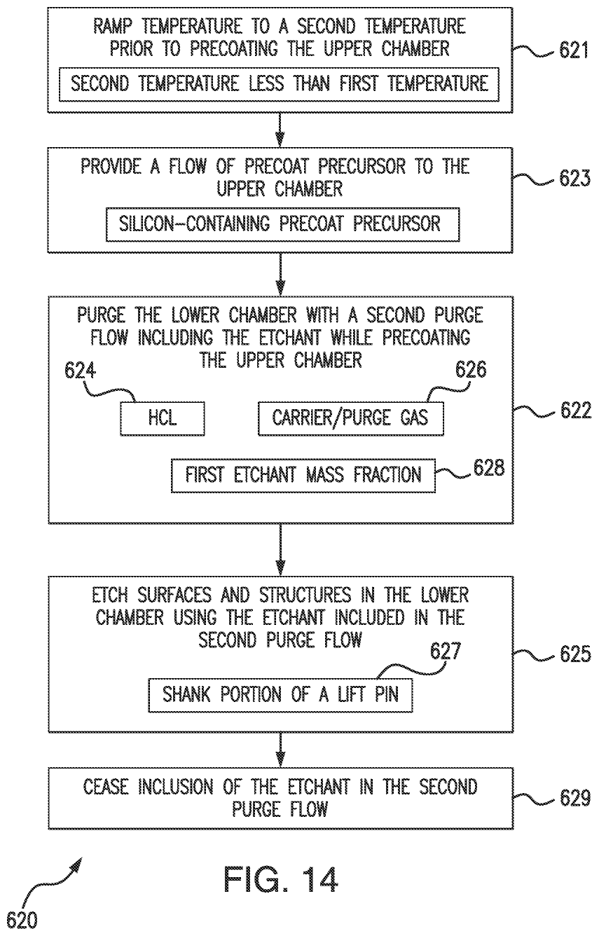

Referring to FIG. 14, it is contemplated that the lower chamber be purged with a second purge flow including the etchant, e.g., the second purge flow 30 (shown in FIG. 6), while the upper chamber is precoated, as shown with box 622. In certain examples, the etchant included in the second purge flow may also include hydrochloric acid (HCl), as shown with box 624. In accordance with certain examples, the second purge flow may also include the carrier/purge gas, which may also consist of (consist essentially) of hydrogen (H₂) gas, as shown with box 626. It is also contemplated that, in accordance with certain examples, the etchant included in the second purge flow form a second etchant mass fraction of the second purge flow, e.g., the second etchant mass fraction 552 (shown in FIG. 11), as shown with box 628. The second etchant mass fraction included in the second purge flow may be between about 0% and about 80% of the first purge flow during the etching of the upper chamber. The second etchant mass fraction included in the second purge flow may be smaller than the first etchant mass fraction included in the first purge flow, as also shown with box 628.

As shown with box 621, precoating the upper chamber may include ramping temperature in the upper chamber to a second temperature, e.g., the predetermined precoating temperature 522 (shown in FIG. 11). In certain examples, the second temperature may be less than the first temperature. As shown with box 623, a flow of silicon-containing precoat precursor, e.g., the precoat precursor 12 (shown in FIG. 2), may be provided to the upper chamber once temperature in the upper chamber reaches the second. It is contemplated that surfaces and/or structures in the lower chamber be etched using the etchant included in the second purge flow during the precoating of the upper chamber, as shown with box 625. In this respect the shank portions of the lift pins disposed in the lower chamber may also be etched by the etchant included in the second purge flow during the precoating of the upper chamber, as shown with box 627. It is further contemplated that flow of the etchant into the lower chamber using the second purge flow cease upon completion of the precoating of the upper chamber, as shown with box 629.

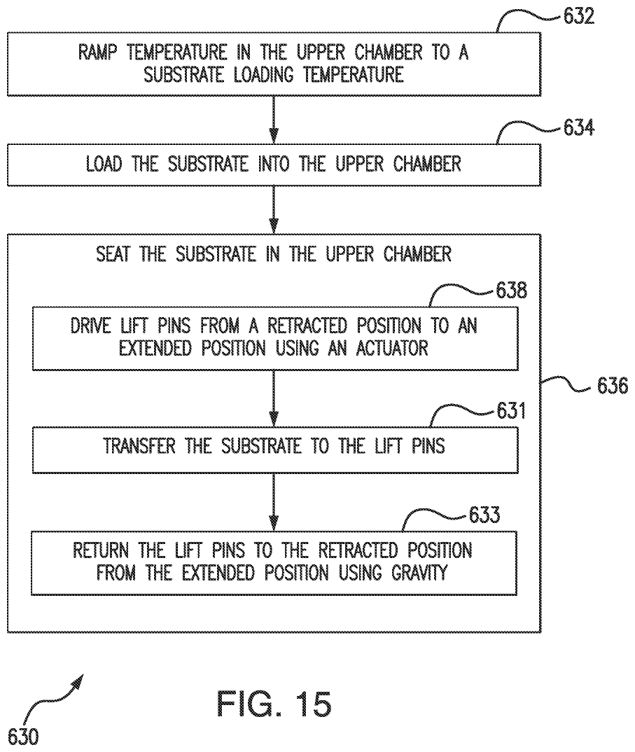

Referring to FIG. 15, loading 630 the substrate into the upper chamber includes ramping (increasing) temperature in upper chamber to a predetermined substrate loading temperature, e.g., to the predetermined loading temperature 530 (shown in FIG. 11), as shown with box 632. Once at the predetermined substrate loading temperature, a substrate, e.g., the substrate 2 (shown in FIG. 1), is loaded into the upper chamber, as shown with box 634. The substrate is then seated in the upper chamber of the reactor, as shown with box 636. Loading may be accomplished by cooperation of a gate valve and a substrate transfer robot, e.g. the gate valve 192 (shown in FIG. 1) and the substrate handler 190 (shown in FIG. 1).

It is contemplated that seating the substrate in the upper chamber include driving the lift pins from a retracted position to an extended position, e.g., from the retracted position 182 (shown in FIG. 3) to the extended position 184 (shown in FIG. 4), a shown with box 638. As the lift pins move from the retracted position to the extended position the substrate is transferred from the substrate handler to the lift pins, as shown with box 631, and the lift pins thereafter returned to the retracted position, as shown with box 633. In certain examples, movement from the retracted position to the extended position may be accomplished by an actuator, e.g., the lift pin actuator 166 (shown in FIG. 3), as also shown with box 638. In accordance with certain examples, return of the lift pins to retracted position may be accomplished by gravity, as also shown with box 633. As will be appreciated by those of skill in the art in view of the present, the etching during the etching 610 and precoating 620 of the shank portions of the lift pins limits (or eliminates) material accumulation, e.g., the material accumulation 34 (shown in FIG. 5), on the lift pins that could otherwise increase resistance to lift pin movement between the retracted position and the extended binding, potentially leading to lift pin binding during substrate transfer and/or substrate seating in the upper chamber of the reactor.

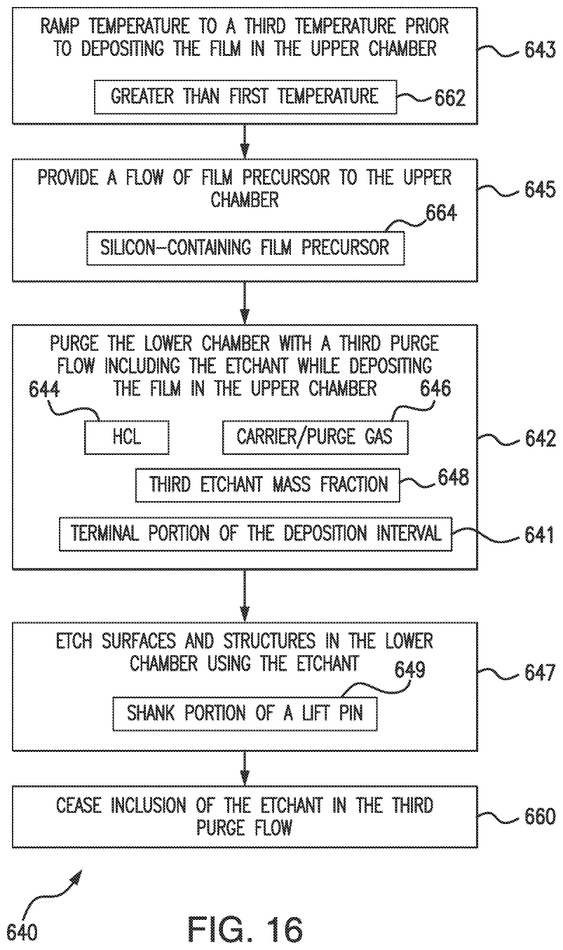

Referring to FIG. 16, it is contemplated that the lower chamber be purged with a third purge flow including the etchant while the film is deposited on the substrate in the upper chamber, e.g., using the third purge flow 32 (shown in FIG. 7), as shown with box 642. The etchant included in the third purge flow may also be hydrochloric acid (HCl), as shown with box 644, and third purge flow may also include the carrier/purge gas, as shown with box 646. The etchant included in the third purge flow may form a third mass fraction of the third mass flow, the third mass fraction may be smaller than the second mass fraction of etchant provided in the second purge flow, and the third mass fraction may further be smaller than the first mass fraction of etchant included in the first purge flow, as shown with box 648. In certain examples, the third mass fraction of etchant included in the third purge flow may vary between about 0% of the third purge flow and about 80% of the third purge flow by mass fraction. In accordance with certain examples, the etchant may be included in the third purge flow during only a portion of the interval within which the film is deposited onto the substrate to limit etching of the film deposited onto the substrate in the upper chamber by the etchant included in the third purge flow, as shown with box 641. For example, the etchant may be included during a terminal 50% of the deposition interval, or a terminal 40% of the deposition interval, or even less than a terminal 30% of the deposition interval to limit etching of the film deposited onto the substrate in the upper chamber by the etchant included in the third purge flow, as also shown by box 641.

As shown with box 643, depositing the film may include ramping temperature in the upper chamber to a third temperature, e.g., the predetermined film deposition temperature 536 (shown in FIG. 11), which may be greater than the second temperature and less than the first temperature. As shown with box 645, a flow of silicon-containing may be provided to the upper chamber to deposit the film onto the substrate, film e.g., the film precursor 14 (shown in FIG. 2). As during the etching and precoating of the upper chamber, it is also contemplated that surfaces and/or structures in the lower chamber be etched using the etchant included in the third purge flow during deposition of the film onto the substrate, such as the shank portion of the lift pin, as shown with box 647 and box 649. It is further contemplated that flow of the etchant into the lower chamber using the third purge flow cease upon completion of the deposition of the film onto the substrate in the upper chamber, as shown with box 670.

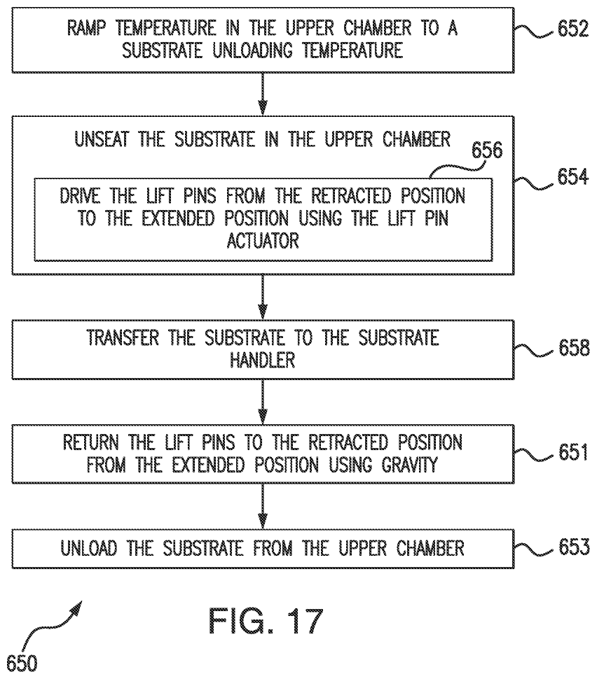

Referring to FIG. 17, unloading 650 the substrate from upper chamber of the reactor includes ramping (i.e. decreasing) temperature from the third temperature to a substrate unloading temperature, e.g., the predetermined unloading temperature 542 (shown in FIG. 11), as shown with box 652. Once temperature in the reactor reaches the predetermined unloading temperature, the lift pins are driven from the retracted position to the extending position using the lift pin actuator to unseat the substrate in the upper chamber, as shown with box 654 and box 656. Once unseated, the substrate is again transferred to the substrate handler and unloaded from the reactor, as shown with box 658, the lift pins returned to the retracted position from the extended position using gravity, as shown with box 651, and the substrate unloaded from the upper chamber of the reactor, as shown with box 653. Advantageously, because the shank portions of the lift pins are etched during the deposition 640 of the film onto the substrate, risk of lift pin binding due to material accumulation on the lift pins is limited (or eliminated) during unloading 650. This can be particularly advantageous during the deposition cycle 500 (shown in FIG. 11) as return the lift pins are unladen (i.e., not supporting a substrate) during their return to the retracted position by operation of gravity.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A semiconductor processing system, comprising:
a gas delivery module;
a chamber body connected to the gas delivery module;
a divider with an aperture fixed within an interior of the chamber body, the divider separating an interior of the chamber body into an upper chamber and a lower chamber, the aperture fluidly coupling the lower chamber to the upper chamber;
a susceptor arranged within the aperture and supported for within the interior of the chamber body for rotation about a rotation axis; and
a controller operably connected to the gas delivery module and having a non-transitory machine-readable memory with instructions recorded on the memory that cause the controller to:
purge the lower chamber with a first purge flow including an etchant while etching the upper chamber of the chamber body;
purge the lower chamber with a second purge flow including the etchant while depositing a precoat in the upper chamber of the chamber body; and
purge the lower chamber with a third purge flow including the etchant while depositing a film onto a substrate in the upper chamber of the chamber body.

2. The semiconductor processing system of claim 1, wherein the first purge flow includes a first etchant mass fraction, wherein the second purge flow includes a second etchant mass fraction, wherein the third purge flow includes a third etchant mass fraction, wherein the third etchant mass fraction is smaller than the second etchant mass fraction, and wherein the second etchant mass fraction is smaller than the first etchant mass fraction.

3. The semiconductor processing system of claim 1, wherein the gas delivery module includes an etchant source and further comprising an injection flange connected to the chamber body, the injection flange fluidly coupling the etchant source to the lower chamber and therethrough to the upper chamber of the chamber body.

4. The semiconductor processing system of claim 1, wherein the gas delivery module includes an etchant source, wherein the system further comprises an exhaust flange connected to the chamber body, the exhaust flange fluidly coupling the etchant source to the lower chamber and therethrough to the upper chamber of the chamber body.

5. The semiconductor processing system of claim 1, wherein the gas delivery module includes an etchant source, and further comprising a tube member connected to a lower wall of the chamber body, the tube member fluidly coupling the etchant source to the lower chamber and therethrough to the upper chamber of the chamber body.

6. The semiconductor processing system of claim 1, further comprising:
an injection flange connected to the chamber body;
a purge conduit connected to the injection flange, the purge conduit fluidly coupled to the lower chamber and therethrough to the upper chamber by the injection flange;
an etchant mass flow controller (MFC) connected to the purge conduit;
a carrier/purge gas MFC connected to the purge conduit;
wherein the controller is operably connected to the etchant MFC and the carrier/purge gas MFC to provide a co-flow of the etchant and a carrier/purge gas to the lower chamber.

7. The semiconductor processing system of the claim 6, wherein the injection flange includes a deposition header fluidly coupling the gas delivery module to the upper chamber of the chamber body and therethrough to the lower chamber of the chamber body.

8. The semiconductor processing system of claim 6, wherein the injection flange includes an etch header fluidly coupling the gas delivery module to the upper chamber of the chamber body and therethrough to the lower chamber of the chamber body.

9. The semiconductor processing system of claim 8, wherein the gas delivery module includes an etchant source, wherein the etchant source is connected to the lower chamber, and wherein the etchant etches a shank portion of a lift pin disposed in the lower chamber.

10. A film deposition method, comprising:
at a semiconductor processing system including a gas delivery module; a chamber body connected to the gas delivery module; a divider with an aperture fixed within an interior of the chamber body, the divider separating an interior of the chamber body into an upper chamber and a lower chamber, the aperture fluidly coupling the lower chamber to the upper chamber; a susceptor arranged within the aperture and supported for within the interior of the chamber body for rotation about a rotation axis; and a controller operably connected to the gas delivery module,
purging the lower chamber with a first purge flow including an etchant while etching the upper chamber of the chamber body;
purging the lower chamber with a second purge flow including the etchant while depositing a precoat in the upper chamber of the chamber body; and
purging the lower chamber with a third purge flow including the etchant while depositing a film onto a substrate in the upper chamber of the chamber body.

11. The film deposition method of claim 10, wherein the first purge flow includes a first etchant mass fraction, wherein the second purge flow includes a second etchant mass fraction, and wherein the second etchant mass fraction is smaller than the first etchant mass fraction.

12. The film deposition method of claim 10, wherein the second purge flow includes a second etchant mass fraction, wherein the third purge flow includes a third etchant mass fraction, and wherein the third etchant mass fraction is smaller than the second etchant mass fraction.

13. The film deposition method of claim 10, wherein the first purge flow includes a first etchant mass fraction, wherein the third purge flow includes a third etchant mass fraction, and wherein the third etchant mass fraction is smaller than the first etchant mass fraction.

14. The film deposition method of claim 10, further comprising:
ceasing flow of the etchant into the lower chamber between the first purge flow and the second purge flow;
ceasing flow of the etchant into the lower chamber between the second purge flow and the third purge flow; and
wherein the third purge flow includes the etchant during only a terminal portion of an interval during which the film is deposited onto the substrate in the upper chamber.

15. The film deposition method of claim 14, wherein the terminal portion is less than 50%, or less than 40%, or less than 30% of the interval during which the film is deposited onto the substrate.

16. The film deposition method of claim 10, further comprising:
heating the susceptor to a first temperature prior to purging the lower chamber with the first purge flow;
heating the susceptor to a second temperature prior to purging the lower chamber with the second purge flow;
heating the susceptor to a third temperature prior to purging the lower chamber with the third purge flow; and
wherein the second temperature is less than the first temperature, and wherein the third temperature is greater than the second temperature.

17. The film deposition method of claim 10, wherein the purging the lower chamber with a first purge flow comprises flowing hydrochloric acid (HCl) into the lower chamber while HCl is flowed through the upper chamber, wherein the HCl flowed into the lower chamber etches a material accumulation on a shank portion of a lift pin disposed in the lower chamber.

18. The film deposition method of claim 10, wherein the purging the lower chamber with a second purge flow includes flowing hydrochloric acid (HCl) into the lower chamber while a silicon-containing precoat precursor is flowed through the upper chamber, wherein the HCl flowed into the lower chamber etches a material accumulation on a shank portion of a lift pin disposed in the lower chamber.

19. The film deposition method of claim 10, wherein purging the lower chamber with a third purge flow comprises flowing hydrochloric acid (HCl) into the lower chamber while a silicon-containing film precursor is flowed through the upper chamber, wherein the HCl flowed into the lower chamber etches a material accumulation on a shank portion of a lift pin disposed in the lower chamber.

20. A lower chamber etchant purge kit, comprising:
an etchant conduit configured to fluidly couple an etchant source to a lower chamber of a chamber body;
a tee fitting configured to fluidly couple a carrier/purge source to the etchant conduit for intermixing a carrier/purge gas with etchant flowing through the etchant conduit;
an etchant mass flow controller (MFC) configured to control mass fraction of etchant intermixed with the carrier/purge gas provided to the lower chamber of the chamber body; and
a computer program product including instructions that, when read by a controller, cause the controller to:
purge the lower chamber of the chamber body with a first purge flow including the etchant using the etchant MFC while etching an upper chamber of the chamber body;
purge the lower chamber with a second purge flow including the etchant using the etchant MFC while depositing a precoat in the upper chamber of the chamber body; and
purge the lower chamber with a third purge flow including the etchant using the etchant MFC while depositing a film onto a substrate seated in the upper chamber of the chamber body.
